(19) United States
(12) Patent Application Publication
(10) Pub. No.: US 2025/0006662 A1
(43) Pub. Date: Jan. 2, 2025

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventor: Yun Cheol HAN, Icheon-si Gyeonggi-do (KR)

(73) Assignee: SK hynix Inc., Icheon-si Gyeonggi-do (KR)

(21) Appl. No.: 18/518,860

(22) Filed: Nov. 24, 2023

(30) Foreign Application Priority Data
Jun. 27, 2023 (KR) 10-2023-0082791

(51) Int. Cl. H01L 23/00; H10B 43/10; H10B 43/27; H10B 43/35

(52) U.S. Cl. CPC H01L 23/562; H10B 43/10; H10B 43/27; H10B 43/35

(57) ABSTRACT

There are provided a semiconductor memory device and a manufacturing method of a semiconductor memory device. The semiconductor memory device includes a stack structure including a cell array region and a contact region extending from the cell array region, a cell plug penetrating the cell array region of the stack structure, a conductive gate contact penetrating the contact region of the stack structure, and a plurality of first support structures bordering a perimeter of the conductive gate contact and disposed to be spaced apart from the center of the conductive gate contact at a first distance.

### CROSS-REFERENCE TO RELATED APPLICATION

The present application claims priority under 35 U.S.C. § 119(a) to Korean patent application number 10-2023-0082791 filed on Jun. 27, 2023, in the Korean Intellectual Property Office, the entire disclosure of which is incorporated by reference herein.

### BACKGROUND

### 1.Technical Field

The present disclosure generally relates to a semiconductor memory device and a manufacturing method of the semiconductor memory device, and more particularly, to a three-dimensional semiconductor memory device and a manufacturing method of the three-dimensional semiconductor memory device.

### 2.Related Art

A semiconductor memory device includes memory cells capable of storing data. A three-dimensional semiconductor memory device may include a three-dimensional memory cell array.

In order to improve the degree of integration of the three-dimensional memory cell array, a stacked number of memory cells may be increased. The stability of a manufacturing process of the three-dimensional semiconductor memory device may deteriorate as the stacked number of memory cells is increased.

### SUMMARY

In accordance with an embodiment of the present disclosure, a semiconductor memory device may include: a stack structure including a cell array region and a contact region extending in a first direction from the cell array region; a cell plug penetrating the cell array region of the stack structure; a conductive gate contact penetrating the contact region of the stack structure; and a plurality of first support structures bordering a perimeter of the conductive gate contact and disposed to be spaced apart from the center of the conductive gate contact at a first distance.

In accordance with an embodiment of the present disclosure, a method of manufacturing a semiconductor memory device may include: forming a stack structure by alternately stacking a plurality of interlayer insulating layers and a plurality of sacrificial layers; forming a first hole and a plurality of second holes to penetrate the stack structure; forming a memory layer and a channel layer in each of the first hole and the plurality of second holes; and forming a third hole in the stack structure, the third hole having a bottom exposing one sacrificial layer among the plurality of sacrificial layers, wherein the plurality of second holes are disposed in substantially a circle to be spaced apart from the center of the third hole at a first distance.

In accordance with an embodiment of the present disclosure, a method of manufacturing a semiconductor memory device may include: alternately stacking a plurality of interlayer insulating layers and a plurality of sacrificial layers; forming a contact hole penetrating at least one of the plurality of interlayer insulating layers and the plurality of sacrificial layers; forming a gap fill layer in the contact hole; forming a cell plug, a plurality of main support structures, and a plurality of support structures, which penetrate the plurality of interlayer insulating layers and the plurality of sacrificial layers; replacing the plurality of sacrificial layers with a plurality of conductive layers; removing the gap fill layer such that one conductive layer among the plurality of conductive layers is exposed through a bottom of the contact hole; and forming a conductive gate contact in a region in which the gap fill layer is removed, wherein the plurality of support structures are arranged in substantially a circle around the contact hole.

### BRIEF DESCRIPTION OF THE DRAWINGS

Examples of embodiments will now be described more fully hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

FIG. 1 is a block diagram illustrating a semiconductor memory device in accordance with an embodiment of the present disclosure.

FIG. 2 is a view illustrating an example of an arrangement of a peripheral circuit structure, a memory cell array, a plurality of bit lines, and a doped semiconductor structure in accordance with embodiments of the present disclosure.

FIG. 3 is a view illustrating another example of the arrangement of the peripheral circuit structure, the memory cell array, the plurality of bit lines, and the doped semiconductor structure in accordance with embodiments of the present disclosure.

FIG. 4 is a plan view illustrating a portion of a semiconductor memory device in accordance with an embodiment of the present disclosure.

FIG. 5 is a sectional view illustrating the semiconductor memory device shown in FIG. 4.

FIGS. 6A, 6B, and 6C are views illustrating examples of second support holes formed around a second contact hole.

FIGS. 7A, 7B, 7C, and 7D are sectional views illustrating a first structure and a second structure of a semiconductor memory device in accordance with embodiments of the present disclosure.

FIGS. 8A and 8B are views illustrating embodiments of a support structure in accordance with the present disclosure.

FIGS. 9A, 9B, 9C, 9D, 9E, 9F, 9G, 9H, 9I, 9J, 9K, 9L, 9M, 9N, 9O, 9P, 9Q, 9R, 9S, 9T, 9U, 9V, 9W, and 9X are sectional views illustrating a method of manufacturing a semiconductor memory device in accordance with an embodiment of the present disclosure.

FIG. 10 is a block diagram illustrating a configuration of a memory system in accordance with an embodiment of the present disclosure.

FIG. 11 is a block diagram illustrating a configuration of a computing system in accordance with an embodiment of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus the present disclosure should not be construed as limited to the embodiments set forth herein.

It will be understood that although the terms first, second, third etc. may be used herein to describe various elements, these elements should not be limited by these terms. These terms are only used to distinguish one element from another element, but not used to define only the element itself or to mean a particular sequence.

Some embodiments may provide a semiconductor memory device and a manufacturing method of the semiconductor memory device, which may improve the stability of a manufacturing process.

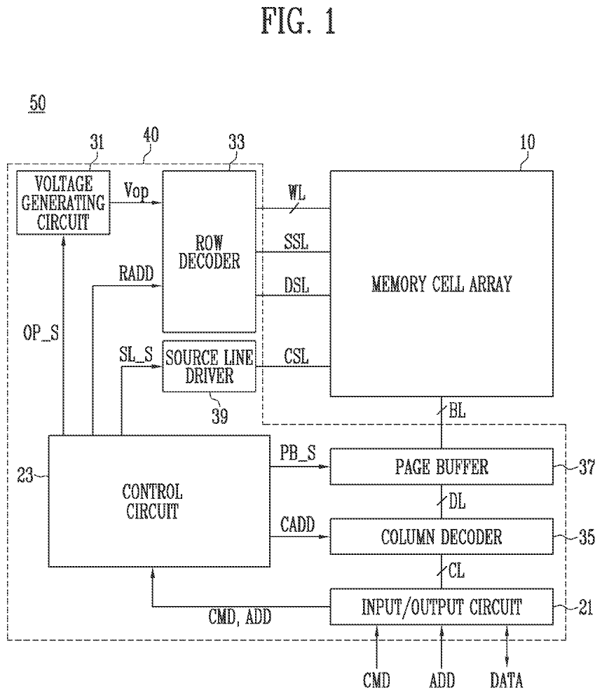

FIG. 1 is a block diagram illustrating a semiconductor memory device in accordance with an embodiment of the present disclosure.

Referring to FIG. 1, the semiconductor memory device 50 may include a peripheral circuit structure 40 and a memory cell array 10.

The peripheral circuit structure 40 may be configured to perform a program operation for storing data in the memory cell array 10, a read operation for outputting data stored in the memory cell array 10, and an erase operation for erasing data stored in the memory cell array 10.

In an embodiment, the peripheral circuit structure 40 may include an input/output circuit 21, a control circuit 23, a voltage generating circuit 31, a row decoder 33, a column decoder 35, a page buffer 37, and a source line driver 39.

The memory cell array 10 may include a plurality of memory cells in which data is stored. The memory cells may be three-dimensionally arranged. The memory cell array 10 may be connected to a drain select line DSL, a plurality of word lines WL, a source select line SSL, a plurality of word lines BL, and a common source line CSL.

The input/output circuit 21 may transfer, to the control circuit 23, a command CMD and an address ADD, which received from an external device (e.g., a memory controller) of the semiconductor memory device 50. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transfer the operating voltages Vop to the drain select line DSL, the word lines WL, and the source select line SSL in response to the row address RADD.

The column decoder 35 may transmit data DATA input from the input/output circuit 21 to the page buffer 37 or transmit data DATA stored in the page buffer 37 to the input/output circuit 21 in response to the column address CADD. The column decoder 35 may exchange data DATA with the input/output circuit 21 through column lines CL. The column decoder 35 may exchange data DATA with the page buffer through data lines DL.

The page buffer 37 may store data DATA received through the bit lines BL in response to the page buffer control signal PB_S. The page buffer 37 may sense a voltage or current of the bit lines BL in a read operation.

The source line driver 39 may control a voltage applied to the common source line CSL in response to the source line control signal SL_S.

In order to improve the degree of integration of the semiconductor memory device, the memory cell array 10 may overlap with the peripheral circuit structure 40.

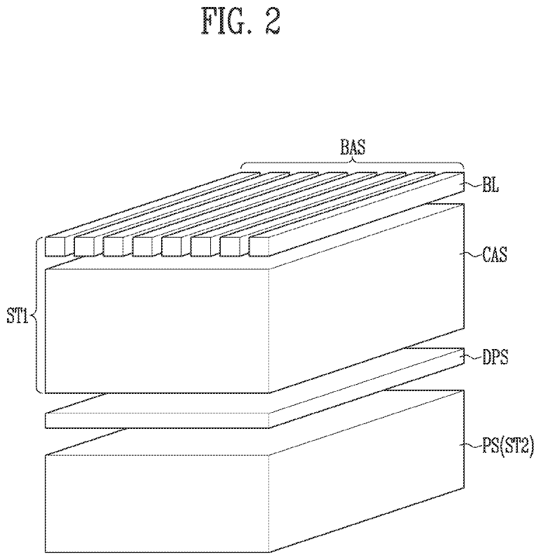

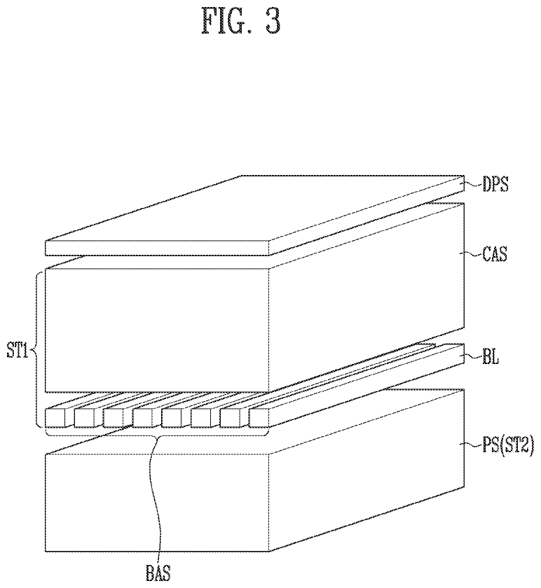

FIG. 2 is a view illustrating an example of an arrangement of a peripheral circuit structure, a memory cell array, a plurality of bit lines, and a doped semiconductor structure in accordance with embodiments of the present disclosure. FIG. 3 is a view illustrating another example of the arrangement of the peripheral circuit structure, the memory cell array, the plurality of bit lines, and the doped semiconductor structure in accordance with embodiments of the present disclosure.

Referring to FIGS. 2 and 3 together, the semiconductor memory device may include a first structure ST1, a second structure ST2, and a doped semiconductor structure DPS. The first structure ST1 may include a cell array structure CAS and a bit line array structure BAS, and the second structure ST2 may include a peripheral circuit structure PS.

The bit line array structure BAS may include a plurality of bit lines BL.

The cell array structure CAS may be disposed between the bit line array structure BAS and the doped semiconductor structure DPS. The cell array structure CAS may include a memory block. The memory block may include a plurality of memory cell strings electrically connected to the bit line array structure BAS and the doped semiconductor structure DPS. Each memory cell string may include a channel structure extending toward a bit line BL corresponding thereto from the doped semiconductor structure DPS.

The doped semiconductor structure DPS may include at least one of an n-type impurity and a p-type impurity. The doped semiconductor structure DPS may be used as any one of a common source region and a well region. The doped semiconductor structure DPS may include at least one of a first conductivity type doped region including the n-type impurity as a majority carrier and a second conductivity type doped region including the p-type impurity as a majority carrier. The first conductivity type doped region may be provided as the common source region, and the second conductivity type doped region may be provided as the well region. The first conductivity type doped region as the common source region may be used as a source layer connected to a common source line.

The peripheral circuit structure PS may be configured to perform a program operation for storing data in a memory cell, a read operation for outputting data stored in a memory cell, and an erase operation for erasing data stored in a memory cell. In an embodiment, the peripheral circuit structure PS may include an input/output circuit, a control circuit, a voltage generating circuit, a row decoder, a column decoder, a page buffer, and the like. More specifically, the peripheral circuit structure PS may include a plurality of transistors, a capacitor, a resistor, and the like.

The peripheral circuit structure PS may include a region overlapping with the doped semiconductor structure DPS, the cell array structure CAS, and the bit line array structure BAS. The peripheral circuit PS may be adjacent to the doped semiconductor structure DPS as shown in FIG. 2, or be adjacent to the bit line array structure BAS as shown in FIG. 3.

The cell array structure CAS may be connected to the peripheral circuit structure PS via a plurality of select lines, a plurality of word lines, the bit array structure BAS, and the doped semiconductor structure DPS. Although not shown in the drawings, each of the first structure ST1 and the second structure ST2 may include at least one of a plurality of interconnections, a plurality of contacts, and a plurality of conductive bonding pads, which are used for electrical connection.

The cell array structure CAS may include a three-dimensional cell array structure including three-dimensionally arranged memory cells. The cell array structure CAS may include a stack structure disposed between the doped semiconductor structure DPS and the bit line array structure BAS.

Hereinafter, a first direction D1 and a second direction D2, which are illustrated in the accompanying drawings, may be defined as two directions intersecting each other on a plane, and a third direction D3 illustrated in the accompanying drawings may be defined as a direction intersecting the plane.

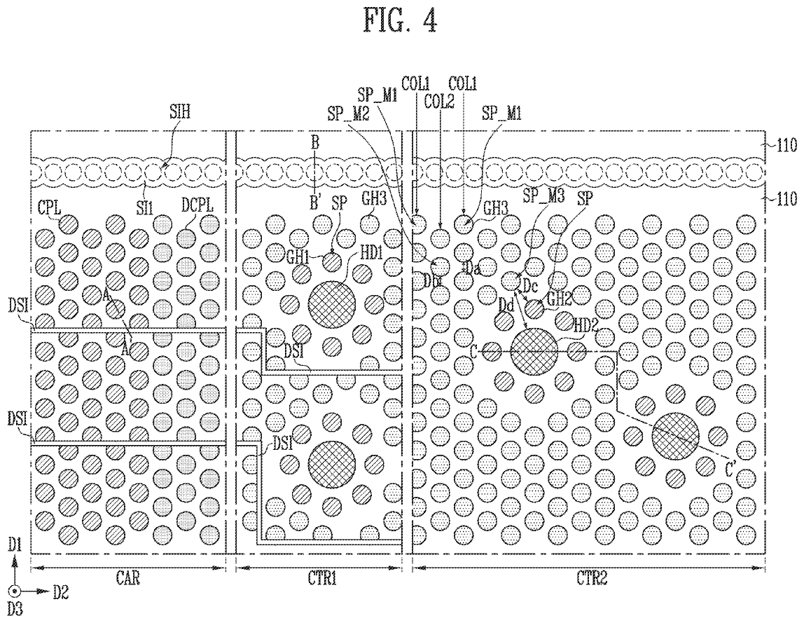

FIG. 4 is a plan view illustrating a portion of a semiconductor memory device in accordance with an embodiment of the present disclosure. In particular, FIG. 4 illustrates a stack structure of the cell array structure CAS shown in FIG. 2 or 3.

Referring to FIG. 4, the semiconductor memory device may include a plurality of stack structures 110 partitioned by a slit SI1. Each stack structure 110 may include a cell array region CAR, a first contact region CTR1, and a second contact region CTR2.

The semiconductor memory device may include a plurality of cell plugs CPL and a plurality of dummy cell plugs DCPL. Each of the plurality of cell plugs CPL and the plurality of dummy cell plugs DCPL may penetrate the cell array region CAR of the stack structure 110 in the third direction DR3. The third direction DR3 may be a length direction of the plurality of cell plugs CPL and the plurality of dummy cell plugs DCPL.

The plurality of cell plugs CPL and the plurality of dummy cell plugs DCPL may be arranged in various forms. In an embodiment, the plurality of cell plugs CPL and the plurality of dummy cell plugs DCPL may be arranged in a zigzag form. For example, as shown in FIG. 4, the plurality of cell plugs CPL and the plurality of dummy cell plugs DCPL may be arranged to be misaligned with each other in the first direction D1 and the second direction D2. The degree of integration of the semiconductor memory device may be improved by the plurality of cell plugs CPL and the plurality of dummy cell plugs DCPL, which are arranged in the zigzag form.

The first contact region CTR1 may extend in the second direction D2 from the cell array region CAR. A plurality of first contact holes HD1 may be formed in the first contact region CTR1. Each of the plurality of first contact holes HD1 may be filled with a conductive material. The conductive material in the first contact hole HD1 may be used as a conductive gate contact connected to some of gate electrodes of a memory cell string. The memory cell string may include at least one source select transistor, a plurality of memory cells, and at least one drain select transistor, which are stacked in the third direction D3 along a cell plug CPL. The gate electrodes of the memory cell string may include a source select line provided as a gate electrode of the source select transistor, a plurality of word lines provided as a plurality of gate electrodes of the plurality of memory cells, and a drain select line provided as a gate electrode of the drain select transistor. In an embodiment, the conductive material in the first contact hole HD1 may be connected to the drain select line.

First support holes GH1 may be formed in the first contact region CTR1. The first support holes GH1 may border the perimeter of the first contact hole HD1 and may be disposed to be spaced apart from the center of the first contact hole HD1. In an embodiment, the first support holes GH1 may be disposed in substantially a circle to be spaced apart from the center of the first contact hole HD1. The first support holes GH1 may be formed using a process of forming the cell plugs CPL of the cell array region CAR. The first support holes GH1 may be filled with a support structure SP.

A drain select isolation structure DS1 may be disposed inside the stack structure 110. The drain select isolation structure DSI may be disposed in the cell array region CAR and the first contact region CTR1 of the stack structure 110, to partition drain select lines of the stack structure 110. The plurality of cell plugs CPL may be divided into first and second cell plugs formed in the cell array region CAR at both sides of the drain select isolation structure DSI. The first and second cell plugs may be controlled by different drain select lines isolated by the drain select isolation structure DSI. The drain select isolation structure DSI may overlap with some of the plurality of cell plugs CPL. However, the embodiment of the present disclosure is not limited thereto, and a dummy cell plug overlapping with the drain select isolation structure DS1 may be additionally disposed between first and second cell plugs adjacent to each other. The plurality of first contact holes HD1 may be divided into first and second drain contact holes formed in the first contact region CTR1 at both the sides of the drain select isolation structure DSI. A conductive gate contact in the first drain contact hole and a conductive gate contact in the second drain contact hole may be connected to different drain select lines isolated by the drain select isolation structure DSI.

The second contact region CTR2 may extend in the second direction D2 from the first contact region CTR1. A plurality of second contact holes HD2 may be formed in the second contact region CTR2. Each of the plurality of second contact holes HD2 may be filled with a conductive material. The conductive material in the second contact hole HD2 may be used as a conductive gate contact connected to others of the gate electrodes of the memory cell string. In an embodiment, a plurality of conductive gate contacts in the plurality of second contact holes HD2 may be individually connected to the plurality of word lines and the source select line.

Second support holes GH2 may be formed in the second contact region CTR2. The second support holes GH2 may border the perimeter of the second contact hole HD2 and may be disposed to be spaced apart from the center of the second contact hole HD2. In an embodiment, the second support holes GH2 may be disposed in substantially a circle to be spaced apart from the center of the second contact hole HD2. The second support holes GH2 may be formed using the process of forming the cell plugs CPL of the cell array region CAR. The second support holes GH2 may be filled with a support structure SP.

A plurality of third support holes GH3 may be formed in each of the first contact region CTR1 and the second contact region CTR2. A plurality of third support holes GH3 disposed in the first contact holes CTR1 may be formed may be formed in a region except regions occupied by the first contact holes HD1 and the first support holes GH1 in the first contact region CTR1. In addition, a plurality of third support holes GH3 disposed in the second contact region CTR2 may be formed in a region except regions occupied by the second contact holes HD2 and the second support holes GH2 in the second contact region CTR2. In an embodiment, the third support holes GH3 may be arranged in a zigzag form in a region except regions occupied by the first contact holes HD1, the first support holes GH1, the second contact holes HD2, and the second support holes GH2. For example, as shown in FIG. 4, the third support holes GH3 may be arranged to be misaligned with each other in the first direction D1 and the second direction D2 in the region except the regions occupied by the first contact holes HD1, the first support holes GH1, the second contact holes HD2, and the second support holes GH2. In another embodiment, the third support holes GH3 may be arranged in a honeycomb form in the region except the regions occupied by the first contact holes HD1, the first support holes GH1, the second contact holes HD2, and the second support holes GH2.

The plurality of third support holes GH3 may be filled with a plurality of main support structures SP_M1, SP_M2, and SP_M3. The plurality of main support structures SP_M1, SP_M2, and SP_M3 may be arranged in a zigzag form. The plurality of main support structures SP_M1, SP_M2, and SP_M3 may include a plurality of first main support structures SP_M1, a plurality of second main support structures SP_M2, and a plurality of third main support structures SP_M3. The plurality of first main support structures SP_M1 and the plurality of second main support structures SP_M2 may constitute first and second columns COL1 and COL2 in each of the first contact region CTR1 and the second contact region CTR2. The first column COL1 and the second column COL2 may be alternately arranged in the second direction D2, and be adjacent to each other. The first column COL1 may include n first main support structures SP_M1 arranged in a line in the first direction D1. The second column COL2 may include (n−1) second main support structures SP_M2 arranged in a line in the first direction D1. The plurality of third main support structures SP_M3 may be adjacent to the support structure SP in the first support hole GH1 and the support structure SP in the second support hole GH2.

The slit SI1 may extend along the cell array region CAR, the first contact region CTR1, and the second contact region CTR2. In an embodiment, in order to form the slit SI1, slit holes SIH arranged in a line may be formed as indicated by a dotted line. After that, the slit SI1 having a line shape may be formed by performing an etching process such that the slit holes SIH can be extended. The slit SI1 shown in FIG. 4 may be used to define a boundary between memory blocks. Although not shown in FIG. 4, a slit having a structure similar to the structure of the slit SI1 shown in FIG. 4 may be formed at an edge of a plane including a plurality of memory blocks.

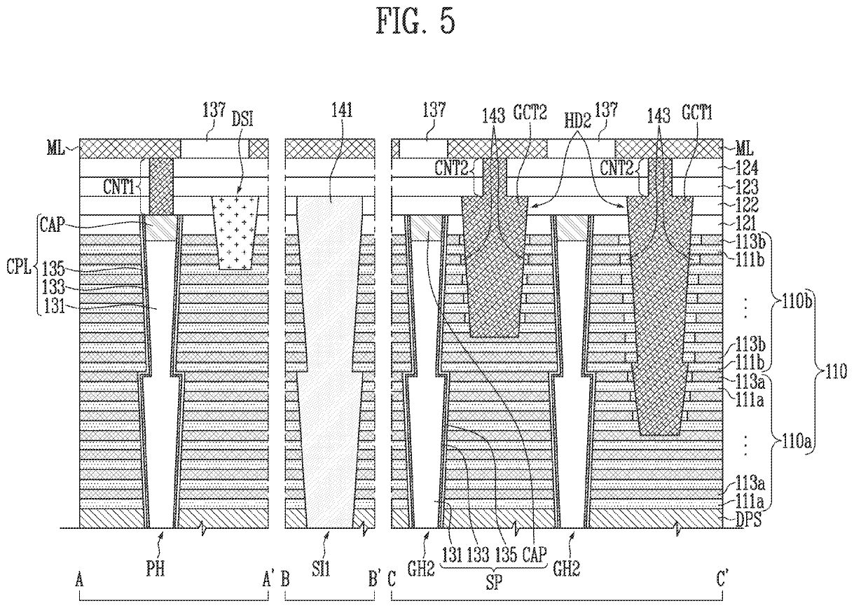

The plurality of second contact holes HD2 may be formed deeper than the first contact hole HD1. The plurality of second contact holes HD2 may be formed to different depths. The stack structure 110 may include a plurality of conductive layers 113a and 113b which are stacked in the third direction D3 and are spaced apart from each other as shown in FIG. 5. The plurality of second contact holes HD2 shown in FIG. 4 may open conductive layers disposed at levels different from a level of a conductive layer opened by the first contact hole HD1, and the conductive layers opened by the plurality of second contact holes HD2 may be disposed at different levels. As the depth of the second contact hole HD2 becomes deeper, the planar area of the second contact hole HD2 may increase. As the planar area of the second contact hole HD2 increases, the area of the second contact region CTR2 which is not supported by the plurality of main support structures SP_M1, SP_M2, and SP_M3 may increase. For example, a separation distance Dd between the second contact hole HD2 and a third main support structure SP_M3 adjacent thereto may be greater than a separation distance Da between the first main support structures SP_M1 of the first column COL1, which can be regularly arranged, or a separation distance Db between the second main support structures SP_M2 of the second column COL2, which can be regularly arranged. As a result, in an embodiment, when the stack structure 110 is formed without the support structure SP, a probability that the stack structure 110 will be bent increases. In accordance with an embodiment of the present disclosure, the support structure SP is disposed between the third main support structure SP_M3 and the second hole HD2, so that the periphery of the second hole HD2 may be firmly supported. A separation distance Dc between the support structure SP and the third main support structure SP_M3 may be different from the separation distance Da between the first main support structures SP_M1 or the separation distance Db between the second main support structures SP_M2. As the plurality of support structures SP are disposed in substantially a circle, using the second contact hole HD2 as a center, in an embodiment, the number of a plurality of support structures SP disposed around the second contact hole HD2 may be maximized, and thus a supporting force through the plurality of support structures SP may be improved.

Similarly to as described above, in an embodiment, the plurality of support structures SP are disposed in substantially a circle around the first contact hole HD1, so that the supporting force may be improved in a process of manufacturing the stack structure 110.

Also, in accordance with an embodiment of the present disclosure, the first to third support holes GH1 to GH3 are formed using the process of forming the cell plugs CPL. Thus, in an embodiment, the number of processes added when the first to third support holes GH1 to GH3 are formed may be minimized, thereby reducing manufacturing cost of the semiconductor memory device.

FIG. 5 is a sectional view illustrating the semiconductor memory device shown in FIG. 4. In FIG. 5, sections of the stack structure 110 taken along lines A-A′, B-B′, and C-C′ shown in FIG. 4 are illustrated. Also, in FIG. 5, a section of the cell plug CPL and the drain select isolation structure DSI, taken along the line A-A′ shown in FIG. 4, a section of the slit SI1 taken along the line B-B′ shown in FIG. 4, and a section of the support structures SP and the conductive gate contacts GCT1 and GCT2, taken along the line C-C′ shown in FIG. 4 are illustrated. In FIG. 5, a conductive line ML, the stack structure 110, and a portion of a doped semiconductor structure DPS are illustrated.

Referring to FIG. 5, a stack structure 110 may include multiple stack structures formed on a doped semiconductor structure DPS. In an embodiment, the stack structure 110 may include a lower stack structure 110a and an upper stack structure 110b, which are formed on the doped semiconductor structure DPS. The lower stack structure 110a may include a plurality of first interlayer insulating layers 111a and a plurality of first conductive layers 113a, which are alternately stacked in the third direction D3. The upper stack structure 110b may include a plurality of second interlayer insulating layers 111b and a plurality of second conductive layers 113b, which are alternately stacked in the third direction D3. Meanwhile, a plurality of insulating layers 121, 122, 123, and 124 may be formed on the top of the stack structure 110. An insulating structure 137 and conductive lines ML inside the insulating structure 137 may be formed on the top of an insulating layer 124. The conductive lines ML may constitute a bit line and a connection line.

The plurality of interlayer insulating layers 111a and 111b and the plurality of conductive layers 113a and 113b may surround a plug hole PH, a slit SI1, and second support holes GH2. Meanwhile, some of the plurality of interlayer insulating layers 111a and 111b and the plurality of conductive layers 113a and 113b may surround second contact holes HD2.

A cell plug CPL may be disposed in the plug hole PH, and support structures SP may be respectively disposed in the second support holes GH2. The second contact holes HD2 may include a second contact hole of a first type, which opens a first conductive layer 113a of the lower stack structure 110a and a second contact hole of a second type, which opens a second conductive layer 113b of the upper stack structure 110b. A first conductive gate contact GCT1 may be disposed in the second contact hole of the first type, and a second conductive gate contact GCT2 may be disposed in the second contact hole of the second type.

Each of the cell plug CPL and the support structures SP may penetrate the stack structure 110 and an insulating layer 121. Each of the cell plug CPL and the support structures SP may include a channel layer 133 and a memory layer 135 between the channel layer 133 and the stack structure 110. Also, each of the cell plug CPL and the support structures SP may further include a capping pattern CAP and a core insulating layer 131, which are surrounded by the channel layer 133. A capping pattern CAP of the cell plug CPL may be connected to a conductive line ML through a bit line contact CNT1. The conductive line ML connected to the cell plug CPL may be used as a bit line.

The plurality of first conductive layers 113a and the plurality of second conductive layers 113b may be used as a source select line, a plurality of word lines, and a drain select line, which are connected to a memory cell string. In an embodiment, at least one second conductive layer from an uppermost layer among the plurality of second conductive layers 113b may be used as the drain select line, at least one first conductive layer from a lowermost layer among the plurality of first conductive layers 113a may be used as the source select line, and the other first and second conductive layers 113a and 113b may be respectively used as the plurality of word lines. A drain select isolation structure DSI may penetrate some of the plurality of conductive layers 113a and 113b. Conductive layers penetrated by the drain select isolation structure DSI may be divided into drain select lines. In an embodiment, two second conductive layers may be used as the drain select line. The drain select isolation structure DSI may be formed to penetrate the two second conductive layers, to divide the two second conductive layers into drain select lines. The drain select lines divided by the drain select isolation structure DSI may be individually connected to conductive gate contacts disposed in different first contact holes HD1 as shown in FIG. 4. Each of the conductive gate contacts disposed in the first contact holes HD1 shown in FIG. 4 may be formed in a structure similar to a structure of the first conductive gate contact GCT1 shown in FIG. 5. However, each of the conductive gate contacts disposed in the first contact holes HD1 shown in FIG. 4 may be formed with a length shorter than a length of the first conductive gate contact GCT1 shown in FIG. 5 to be in contact with a second conductive layer for the drain select line, which corresponds thereto.

Referring to FIG. 5, the slit SI1 may penetrate the stack structure 110 and insulating layers 122 and 123. The slit SI1 may extend to the inside of the doped semiconductor structure DSP. A vertical structure 141 may be disposed inside the slit SI1. In an embodiment, the vertical structure 141 may include an insulating material filling the slit SI1. In another embodiment, the vertical structure 141 may include an insulating layer extending along a sidewall of the stack structure 110 and a conductive layer filling a central region of the slit SI1. The conductive layer may be connected to the doped semiconductor structure DSP. In still another embodiment, the vertical structure 141 may include an insulating layer in contact with the stack structure 110 and the doped semiconductor structure DSP and a gap fill layer on the insulating layer. The gap fill layer of the vertical structure 141 may be formed of various materials including amorphous silicon, metal, and the like.

Because, in an embodiment, the support structures SP have the same configuration as the cell plug CPL, the support structures SP may be formed using a process of forming the cell plug CPL. Thus, in an embodiment, the number of processes required to form the support structures SP may be decreased.

As described above with reference to FIG. 4, the support structures SP may be disposed in substantially a circle around the first conductive gate contact GCT1 or the second conductive gate contact GCT2. Accordingly, in an embodiment, although a planar area of the first conductive gate contact GCT1 or the second conductive gate contact GCT2 is formed relatively wide as compared with the main support structures SP_M1, SP_M2, and SP_M3 shown in FIG. 4, a supporting force may be compensated through the support structures SP in a region at the periphery of the first conductive gate contact GCT1 or the second conductive gate contact GCT2, in which the density of the main support structures SP_M1, SP_M2, and SP_M3 becomes low. Thus, in an embodiment, a phenomenon may be reduced or prevented, in which the stack structure 110 is bent or damaged at the periphery of a conductive gate contact such as the first conductive gate contact GCT1 or the second conductive gate contact GCT2 in a manufacturing process of the semiconductor memory device.

Each of the first conductive gate contact GCT1 and the second conductive gate contact GCT2 may be in contact with a conductive layer exposed through a bottom surface of a second contact hole HD2 corresponding thereto, and be insulated from conductive layers surrounding a sidewall of the corresponding second contact hole HD2 by contact insulating patterns 143. The contact insulating pattern 143 may surround a sidewall of each of second contact holes HD2. The contact insulating pattern 143 may be interposed between two interlayer insulating layers adjacent to each other in the third direction D3. The contact insulating pattern 143 may extend to surround a sidewall of a corresponding gate contact among the first and second conductive gate contacts GCT1 and GCT2. Accordingly, each of the first conductive gate contact GCT1 and the second conductive gate contact GCT2 may be insulated from at least one conductive layer located on the top of a conductive layer corresponding thereto. Meanwhile, each of the first conductive gate contact GCT1 and the second conductive gate contact GCT2 may be connected to a conductive line ML corresponding thereto through a connection contact CNT2. The conductive line ML connected to each of the first conductive gate contact GCT1 and the second conductive gate contact GCT2 may be used as a connection line connected to the row decoder 33 of the peripheral circuit structure 40 shown in FIG. 1.

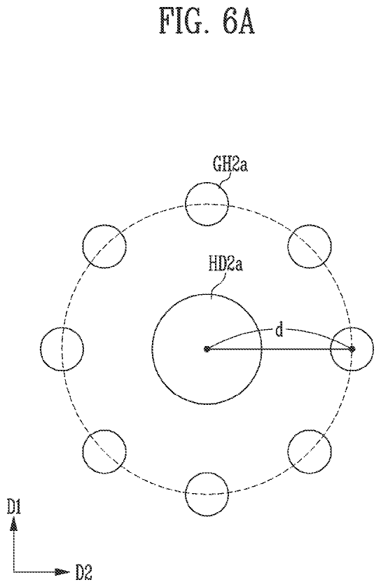

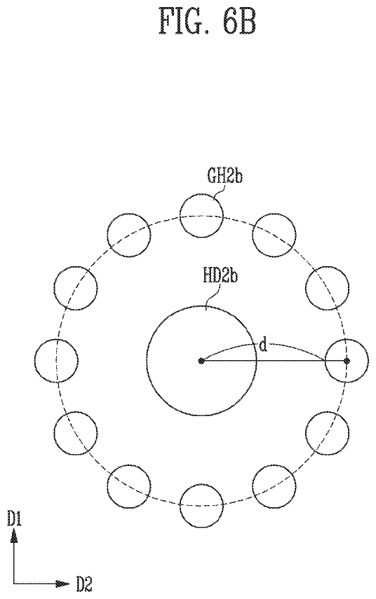

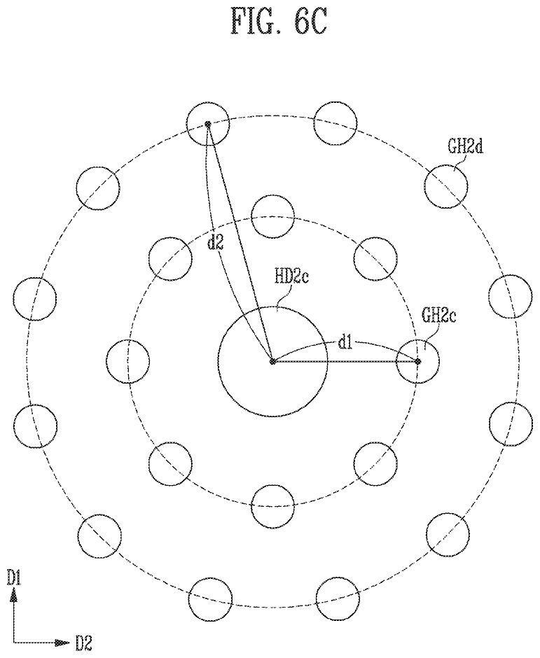

FIGS. 6A to 6C are views illustrating examples second support holes formed around a second contact hole.

Referring to FIG. 6A, second support holes GH2a may be disposed in substantially a circle to be spaced apart from a center of a second contact hole HD2a at a distance d. Although an embodiment in which a total of 8 second support holes GH2a are disposed around the second contact hole HD2a is illustrated in FIG. 6A, the present disclosure is not limited thereto, and various numbers of second support holes may be disposed in substantially a circle around a second contact hole. For example, as shown in FIG. 6B, 12 second support holes GH2b may be disposed in substantially a circle to be spaced apart from a center of the second contact hole HD2b.

Referring to FIGS. 6A and 6B, second support holes disposed to be spaced apart from a second contact hole at a single distance d. However, the present disclosure is not limited thereto, and second support holes of two groups, which are disposed to be spaced apart from a second contact hole at two different distances are also possible. Referring to FIG. 6C, second support holes GH2c of a first group, which are disposed to be spaced apart from a center of a second contact hole HD2c at a first distance d1, and second support holes GH2d of a second group, which are disposed to be spaced apart from the center of the second contact hole HD2c at a second distance d2, may be formed. The second distance d2 may be greater than the first distance d1. In an embodiment, a number of the second support holes GH2d of the second group may be greater than a number of the second support holes GH2c of the first group. However, the present disclosure is not limited thereto. In an embodiment, a number of the second support holes GH2d of the second group may be equal to a number of the second support holes GH2c of the first group. Although second support holes of two groups, which are disposed to be spaced from a second contact hole at two different distances, are illustrated in FIG. 6C, the present disclosure is not limited thereto. For example, second support holes of three or more groups, which are disposed to be spaced apart from a second contact hole at different distances, may be formed.

Each of the second support holes GH2a, GH2b, GH2c, and GH2d shown in FIGS. 6A to 6C may be filled with the support structure SP shown in FIG. 5.

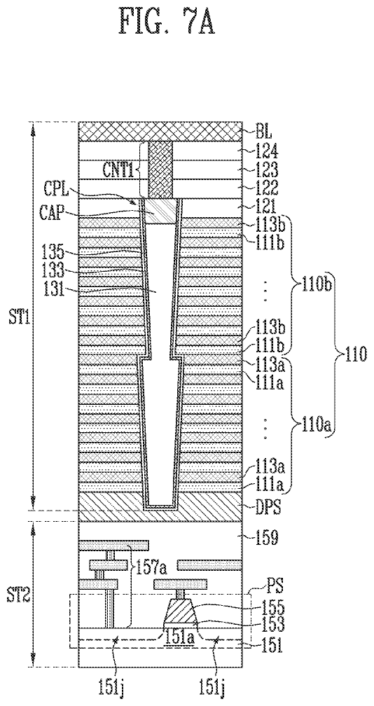

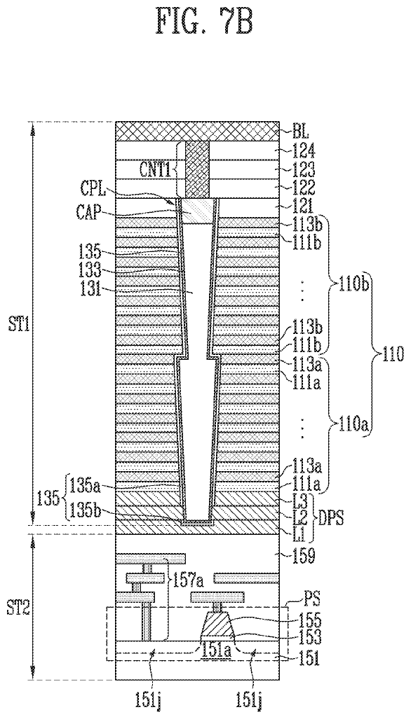

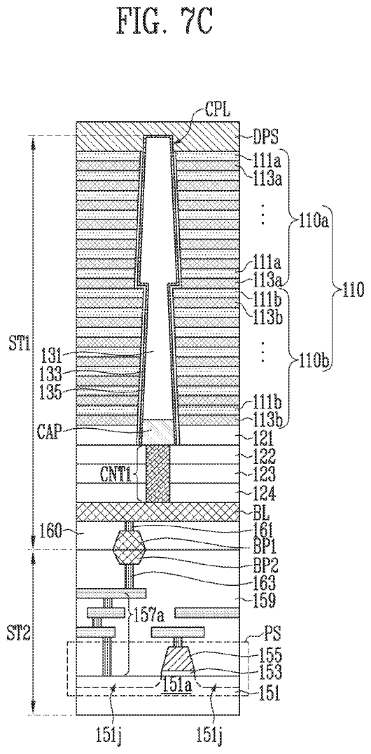

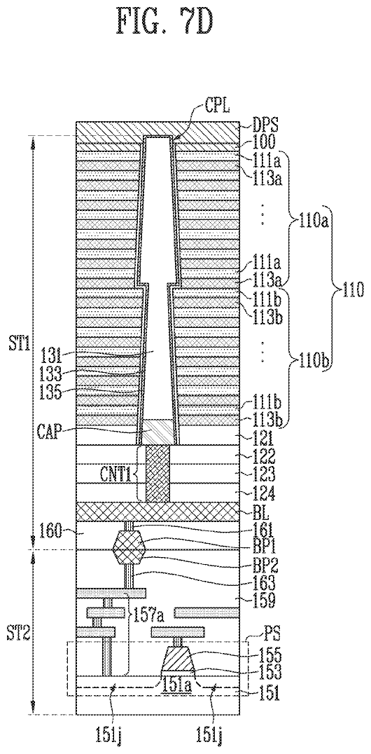

FIGS. 7A, 7B, 7C, and 7D are sectional views illustrating a first structure and a second structure of a semiconductor memory device in accordance with embodiments of the present disclosure.

Referring to FIGS. 7A to 7D, the first structure ST1 may include the cell array structure described with reference to FIGS. 2 and 3, and a bit line BL. The cell array structure may include a stack structure 110 disposed between a doped semiconductor structure DPS and the bit line BL and a cell plug CPL penetrating the stack structure 110.

The stack structure 110 may include a plurality of interlayer insulating layers 111a and 111b and a plurality of conductive layers 113a and 113b, which are alternately stacked in a direction in which the doped semiconductor structure DPS faces the bit line BL. The plurality of conductive layers 113a and 113b may form the source select line SSL, the drain select line DSL, and the plurality of word lines WL, which are shown in FIG. 1. Meanwhile, insulating layers 121, 122, 123, and 124 may be formed on the top of the stack structure 110. The bit line BL may be formed on the top of the insulating layers 121, 122, 123, and 124.

The cell plug CPL may include a channel layer 133 and a memory layer 135 between the channel layer 133 and the stack structure 110. Some regions of the memory layer 135 may be used as data storage regions of a plurality of memory cells, and other regions of the memory layer 135 may be used as gate insulating layers of a drain select transistor and a source select transistor. Some regions of the channel layer 133 may be used as channel regions of the plurality of memory cells, the drain select transistor, and the source select transistor. In an embodiment, the cell plug CPL may also include a core insulating layer 131.

The cell plug CPL may further include a capping pattern CAP used as a junction. The capping pattern CAP may be in contact with the channel layer 133. The capping patter CAP and the channel layer 133 may form a channel structure. The channel structure may be formed in a tubular shape having a central region filled with the core insulating layer 131 and the capping pattern CAP. The capping pattern CAP may be formed of a doped semiconductor layer including at least one of a p-type impurity and an n-type impurity. In an embodiment, the capping pattern CAP may be formed of an n-type doped semiconductor layer including the n-type impurity as a majority carrier.

The first structure ST1 may further include insulating layers 121, 122, 123, and 124 covering the stack structure 110. The bit line BL may be formed on the top of the insulating layers 121, 122, 123, and 124. The bit line BL may be in contact with the cell plug CPL. In an embodiment, the bit line BL may be connected to the channel structure via a bit line contact CNT1 inside the insulating layers 122, 123, and 124.

The channel layer 133 may include a portion connected to the doped semiconductor layer DPS.

Referring to FIG. 7A, the channel layer 133 may penetrate the memory layer 133, and include an end portion in contact with the doped semiconductor structure DPS. The doped semiconductor structure DPS may include at least one of an n-type impurity and a p-type impurity. In an embodiment, the end portion of the channel layer 133 may be in contact with a common source region of the doped semiconductor structure DPS, including the n-type impurity as a majority carrier.

Referring to FIG. 7B, the doped semiconductor structure DPS may be connected to a side portion of the channel layer 133. The doped semiconductor structure DPS may include a first semiconductor layer L1 and a second semiconductor layer L2. The second semiconductor layer L2 may be disposed between the first semiconductor layer L1 and the stack structure 110. The doped semiconductor structure DPS may further include a third semiconductor layer L3 between the second semiconductor layer L2 and the stack structure 110. The third semiconductor layer L3 may be omitted in some embodiments.

Each of the first to third semiconductor layers L1 to L3 may include at least one of an n-type impurity and a p-type impurity. In an embodiment, each of the first to third semiconductor layers L1 to L3 may include the n-type impurity as a majority carrier. In another embodiment, the first semiconductor layer L1 may include the p-type impurity as a majority carrier, and each of the second and third semiconductor layers L2 and L3 may include the n-type impurity as a majority carrier.

The second semiconductor layer L2 may penetrate a side portion of the memory layer 135 to be in contact with the side portion of the channel layer 133. Accordingly, the memory layer 135 may be isolated into a cell-side pattern 135a and a dummy pattern 135b. The cell-side pattern 135a may be interposed between the channel layer 133 and the stack structure 110. The dummy pattern 135b may be interposed between the channel layer 133 and the first semiconductor layer L1.

Referring to FIG. 7C, the channel layer 133 may include a protrusion part protruding toward the doped semiconductor structure DPS as compared with the memory layer 135. The protrusion part of the channel layer 133 may be in contact with the doped semiconductor structure DPS. The doped semiconductor structure DPS may include at least one of an n-type impurity and a p-type impurity.

Referring to FIG. 7D, a semiconductor layer 100 may be disposed between the doped semiconductor structure DPS and the stack structure 110. The semiconductor layer 100 may include a semiconductor material such as silicon or germanium. The semiconductor layer 100 may include a single crystalline semiconductor material or a polycrystalline semiconductor material. The semiconductor layer 100 may include an undoped semiconductor material or include a doped semiconductor material including at least one of n-type and p-type impurities.

The memory layer 135 and the channel layer 133 may extend to the inside of the semiconductor layer 100. The channel layer 133 may extend to the inside of the doped semiconductor structure DPS, and be in contact with the doped semiconductor structure DPS. The doped semiconductor structure DPS may include any one of an n-type impurity and a p-type impurity.

Referring to FIG. 7A to 7D, the second structure ST2 may include a semiconductor substrate 151, a peripheral circuit structure PS, a second insulating structure 159, and a plurality of interconnections 157a.

The semiconductor substrate 151 may include an active region 151a partitioned by an isolation layer (not shown). The peripheral circuit structure PS may include a transistor. A gate insulating layer 153 and a gate electrode 155 of the transistor may be stacked on the active region 151a of the semiconductor substrate 151. Source and drain junctions 151j of the transistor may be formed in the active region 151a at both sides of the gate electrode 155. The plurality of interconnections 157a may include sub-interconnections individually connected to the gate electrode 155 and the source/drain junctions 151j.

The semiconductor substrate 151 and the peripheral circuit structure PS may be covered with the second insulating structure 159, and the plurality of interconnections 157a may be disposed inside the second insulating structure 159.

Referring to FIGS. 7A and 7B, a process of forming the doped semiconductor structure DPS and a process of forming the first structure ST1 may be performed on the second structure ST2.

Referring to FIGS. 7C and 7D, a process of the first structure ST1 and a process of forming the second structure may be individually performed. The first structure ST1 may further include a first insulating structure 160, and a first contact 161 and a first conductive bonding pad BP1, which are disposed in the first insulating structure 160, and the second structure ST2 may further include a second contact 163 and a second conductive bonding pad BP2, which are disposed in the second insulating structure 159. The first conductive bonding pad BP1 of the first structure ST1 and the second conductive bonding pad BP2 of the second structure ST2 may be connected to each other through a bonding process. The doped semiconductor structure DPS may be provided after the bonding process.

The first conductive bonding pad BP1 may be electrically connected to any one of the bit line BL or any one of the conductive layers 113a and 113b via the first contact 161. The second conductive bonding pad BP2 may be electrically connected to any one of element constituting the peripheral circuit structure PS via the second contact 163. In an embodiment, as shown in FIGS. 7C and 7D, the first conductive bonding pad BP1, the second conductive bonding pad BP2, and the second contact 163 may be used to electrically connect the bit line BL to a transistor constituting the page buffer 37 shown in FIG. 1.

Referring to FIGS. 7A to 7D, a cell array region of the stack structure 110, in which cell plugs CPL are formed, and the doped semiconductor structure DPS and the second structure ST2, which overlap with the cell array region, have been described. The stack structure 110 shown in FIGS. 7A to 7D may extend to the first contact region CTR1 and the second contact region CTR2 as shown in FIG. 4. The stack structure 110 shown in FIGS. 7A to 7D may include support structures having the same structure as the cell plug CPL in the first contact region and the second contact region, like the embodiment described with reference to FIGS. 4 and 5. The support structures may be disposed in substantially a circle around a conductive gate contact. The support structures may be connected to the bit line through the capping pattern CAP and the bit line contact CNT1. In an embodiment, each of the support structures may be insulated from conductive lines such as the bit line BL by the insulating layers 122, 123, and 124 not to be involved in an operation of the semiconductor memory device even when each of the support structures is formed in the same structure as the cell plug CPL.

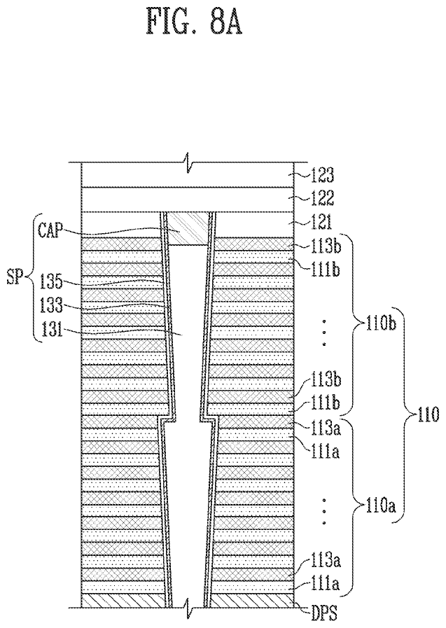

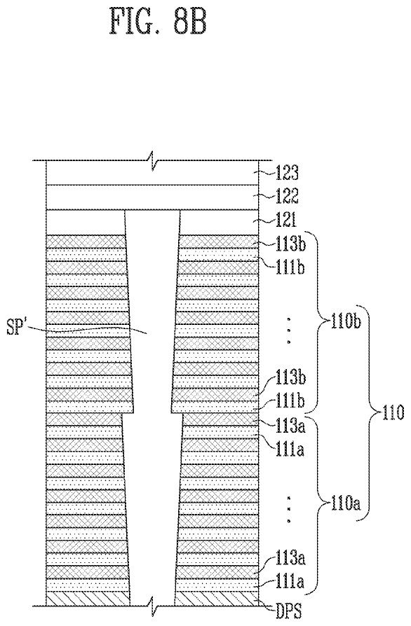

FIGS. 8A and 8B are views illustrating embodiments of a support structure in accordance with the present disclosure.

Referring to FIG. 8A, a support structure SP may be formed in the same shape as the cell pug CPL shown in FIG. 5 as described above. Therefore, the support structure SP may include a memory layer 135 in contact with the stack structure 110, a channel layer 133 inside the memory layer 135, and a core insulating layer 131 and a capping pattern CAP, which are surrounded by the channel layer 133. However, the present disclosure is not limited thereto. As shown in FIG. 8B, a support structure SP′ may be formed of an insulating material filling a support hole penetrating the stack structure 110. When the support hole is formed, the support hole may be formed using a process of forming the plug hole for the cell plug CPL shown in FIG. 5.

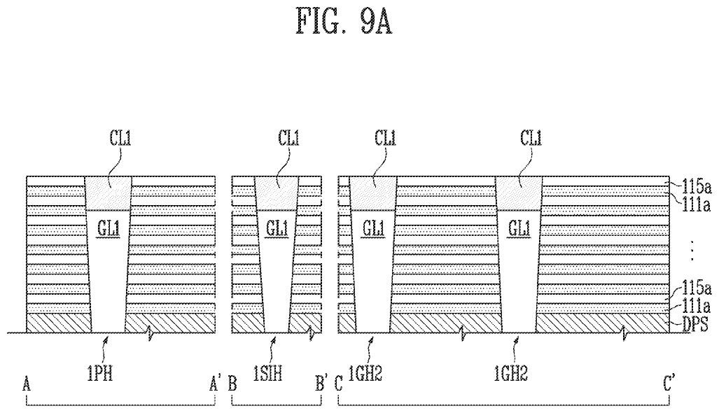

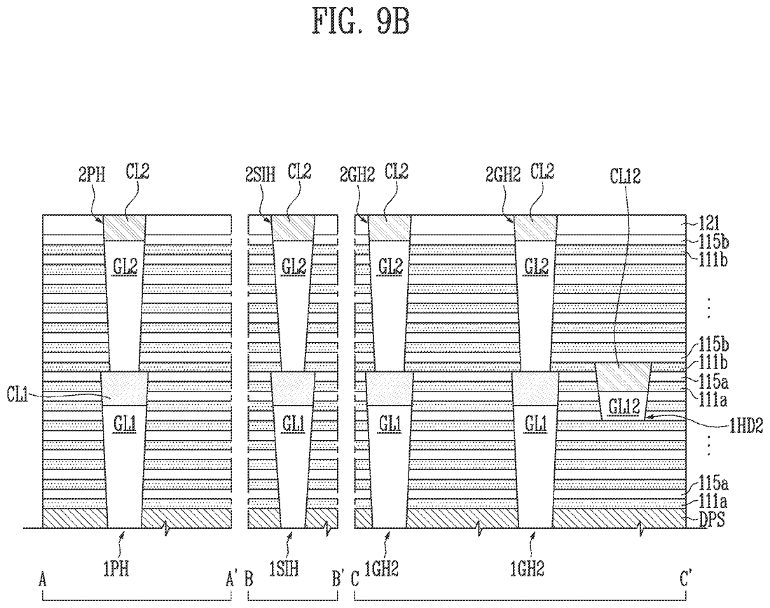

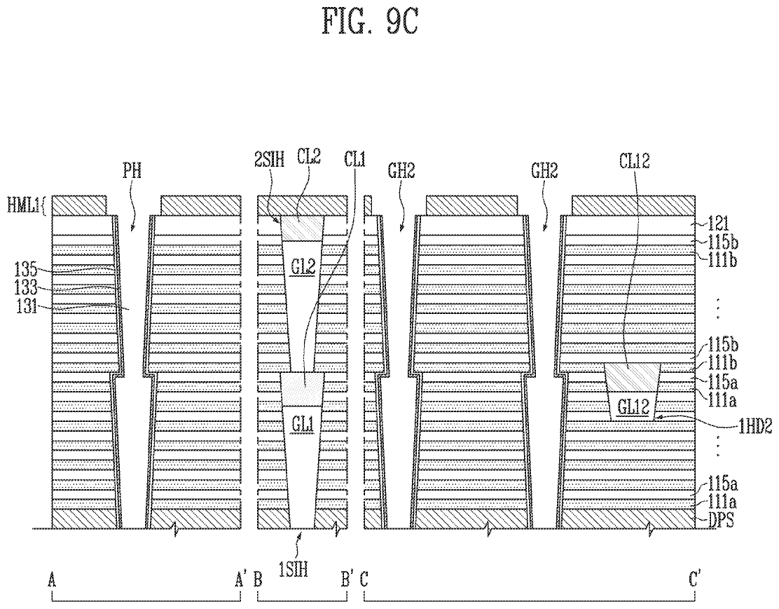

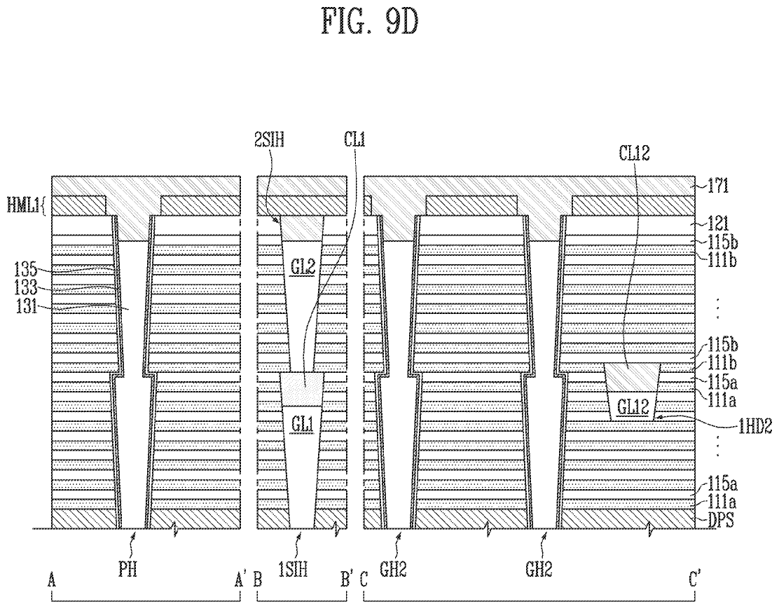

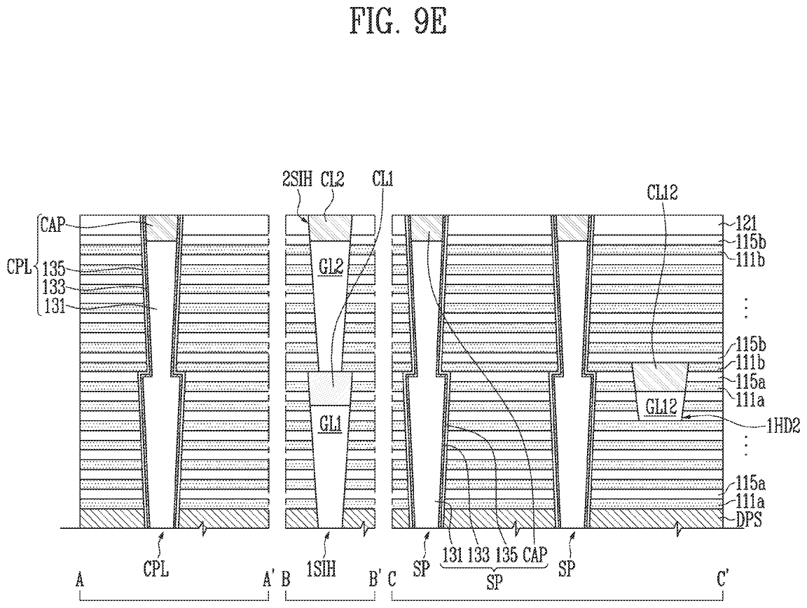

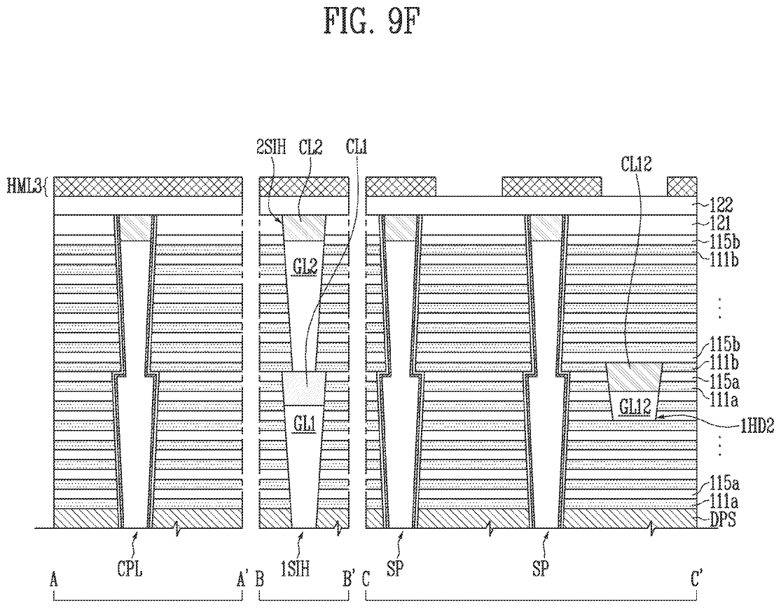

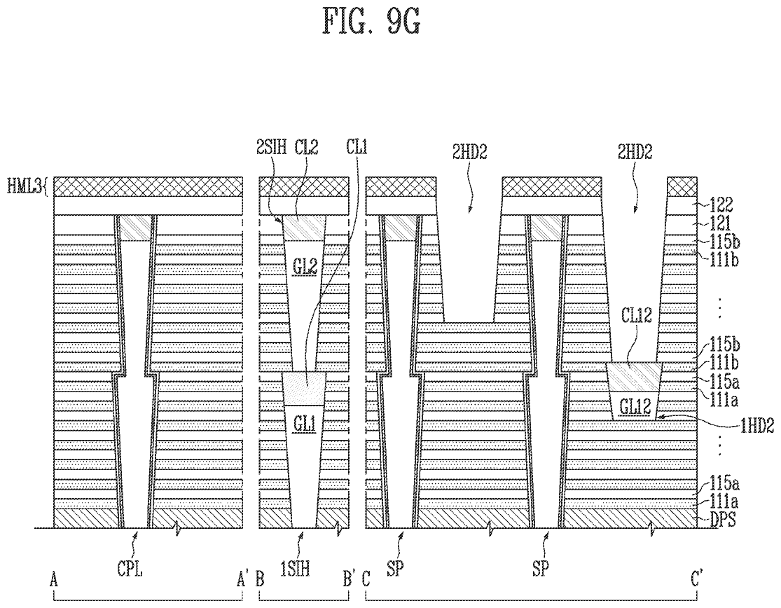

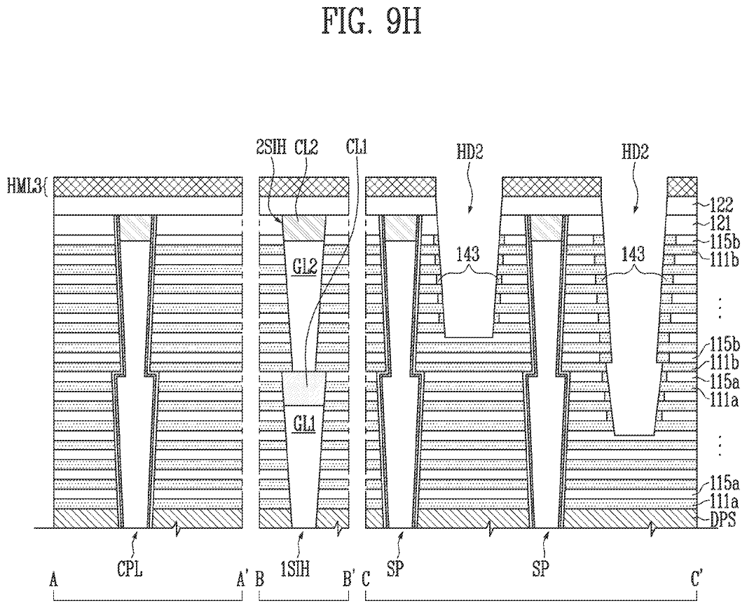

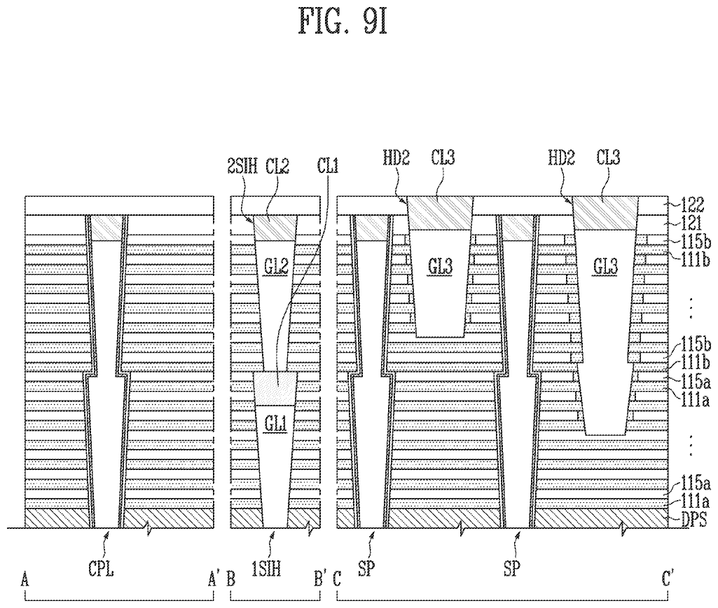

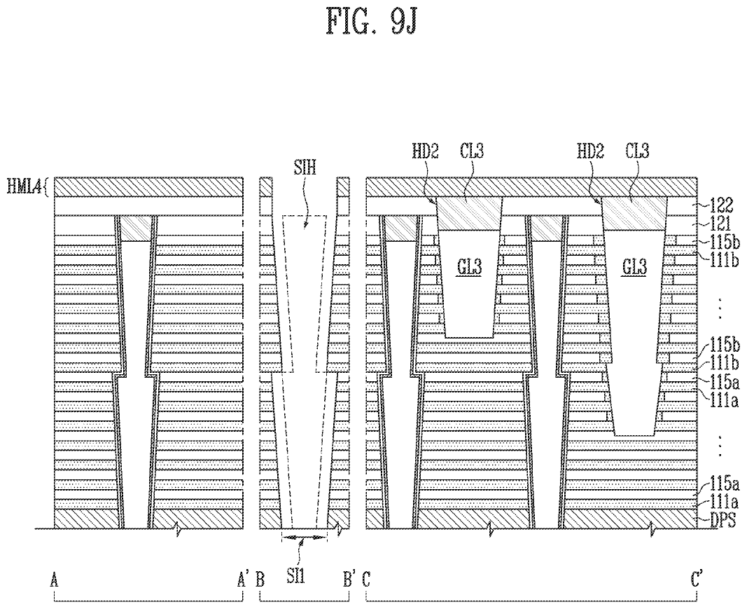

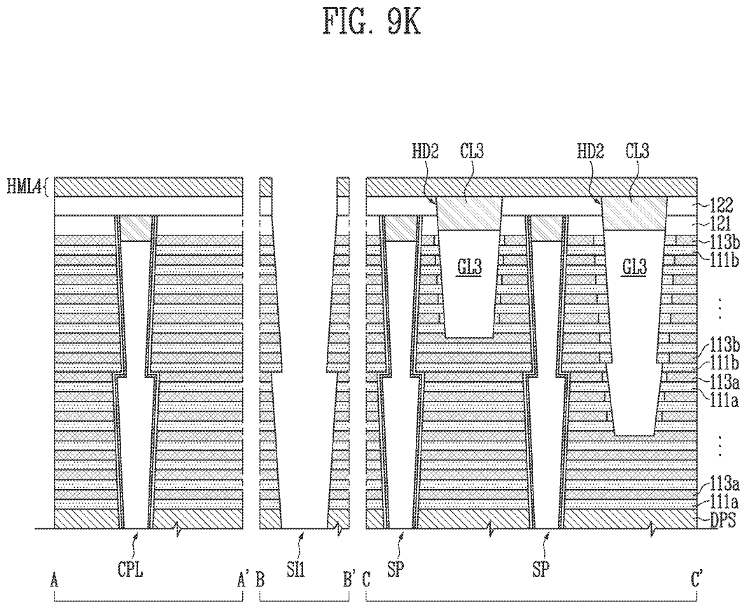

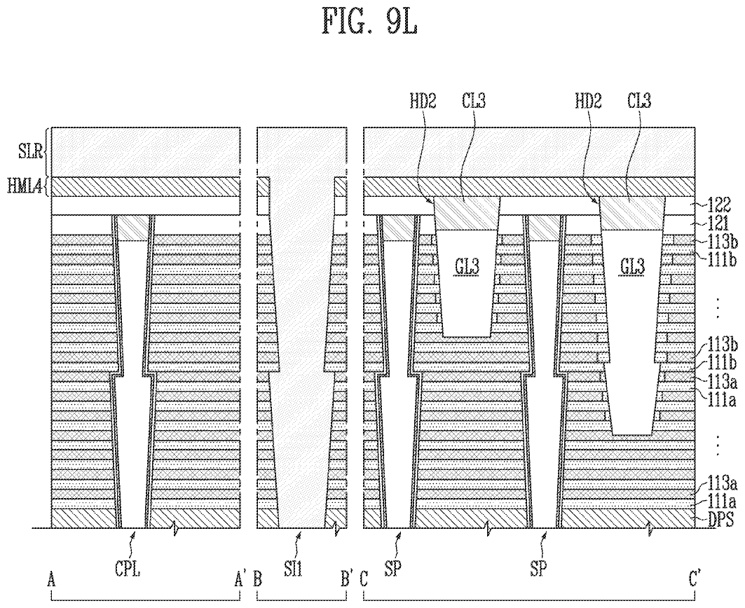

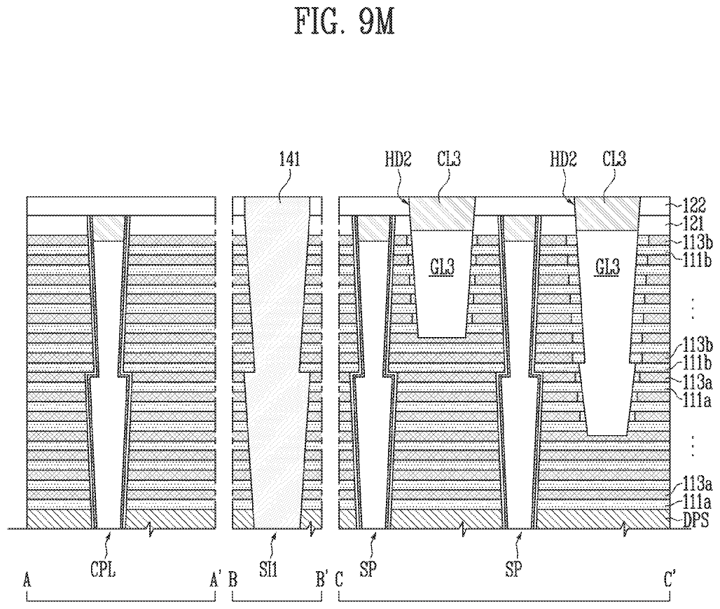

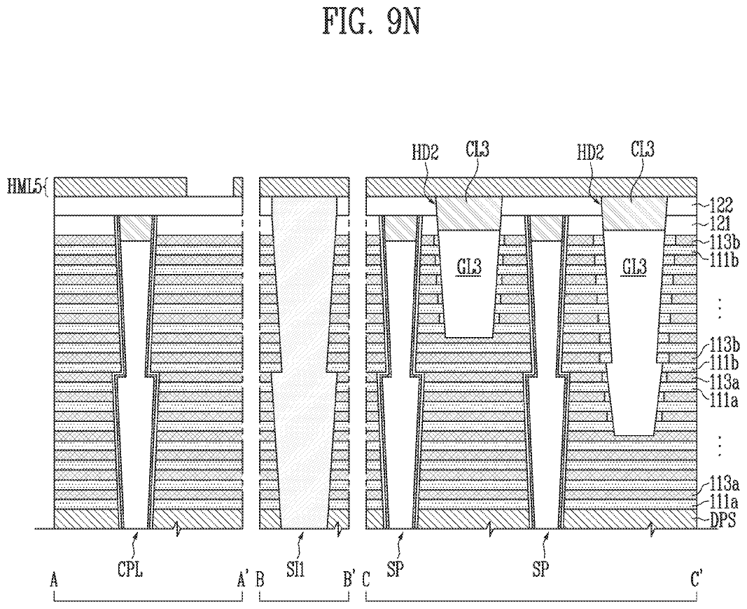

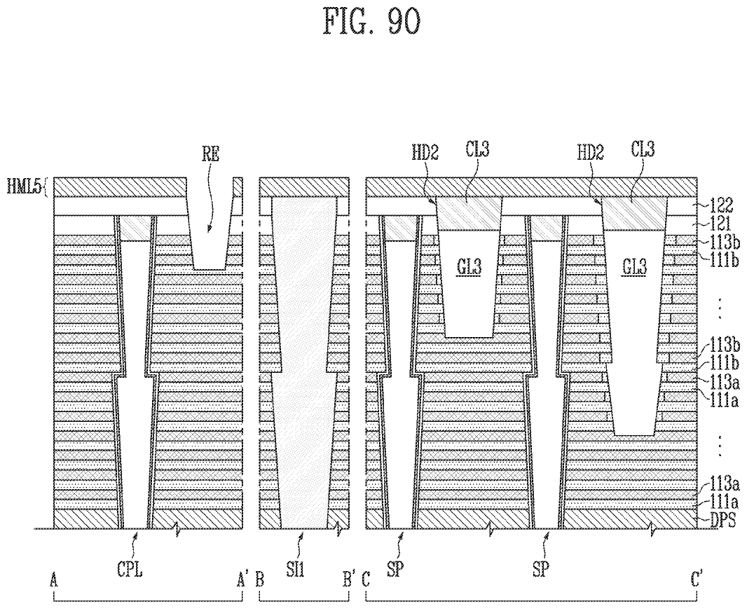

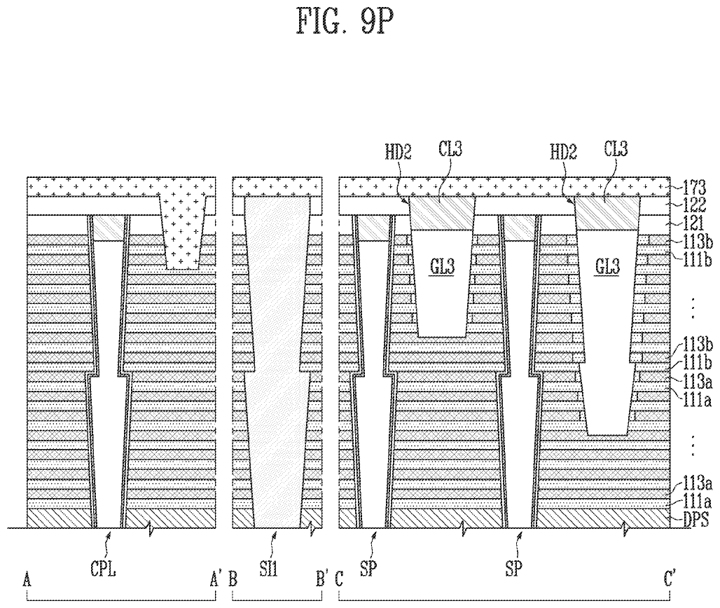

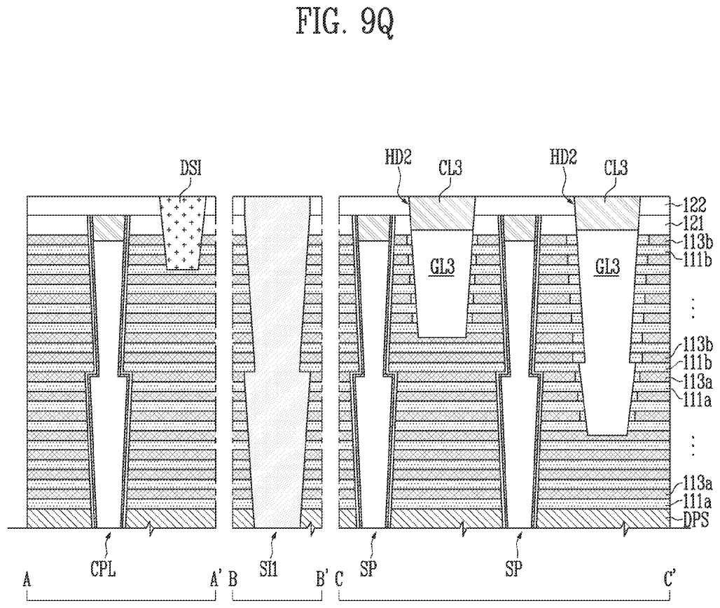

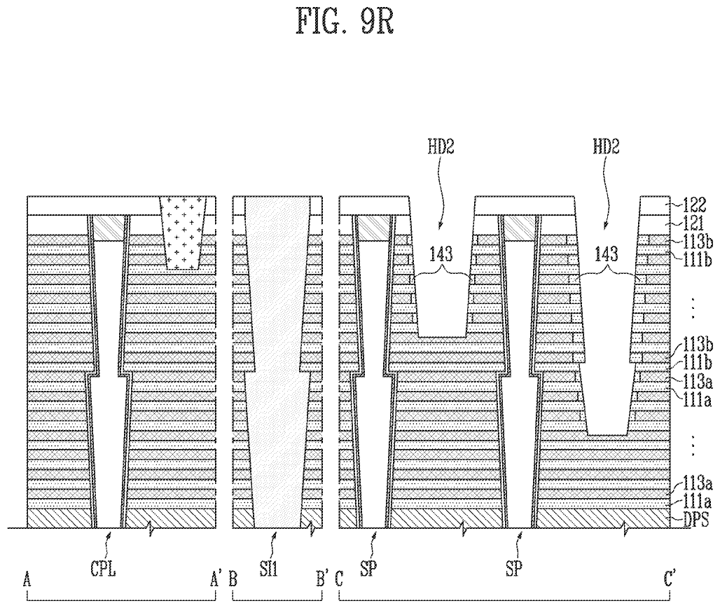

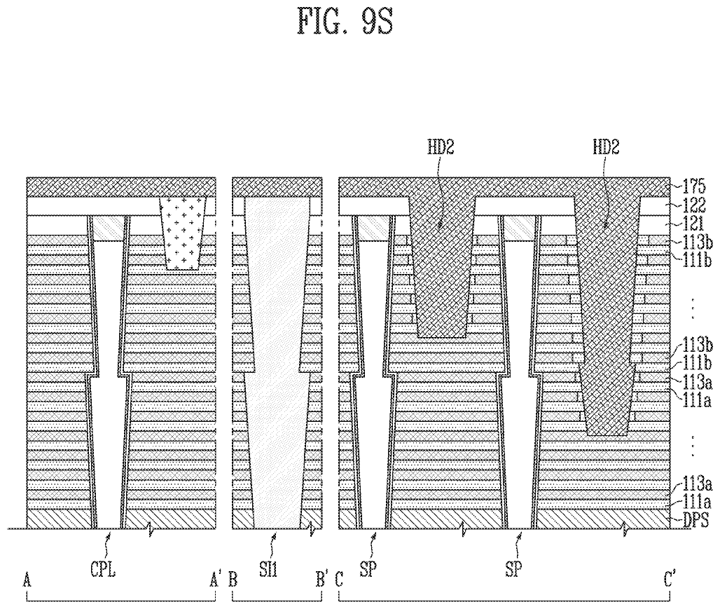

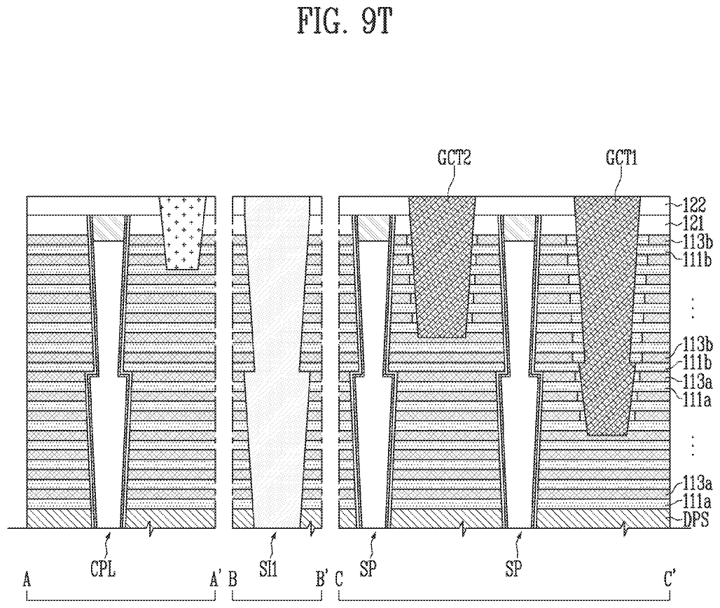

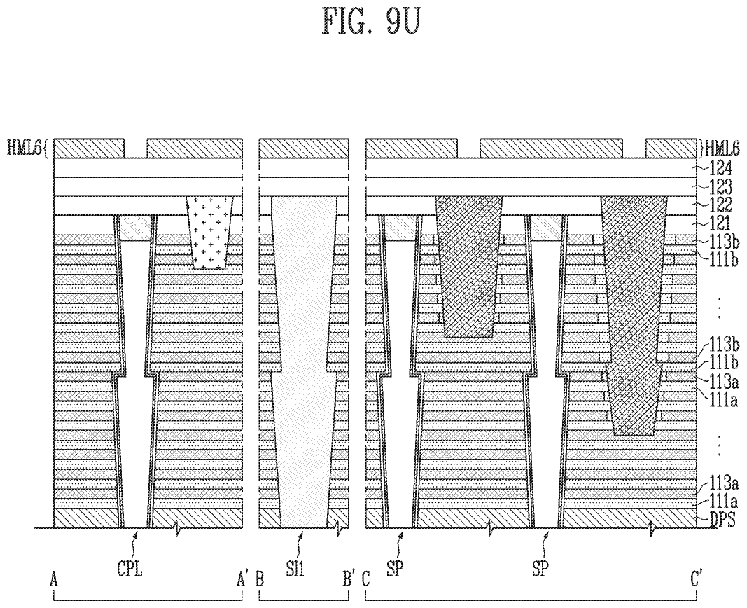

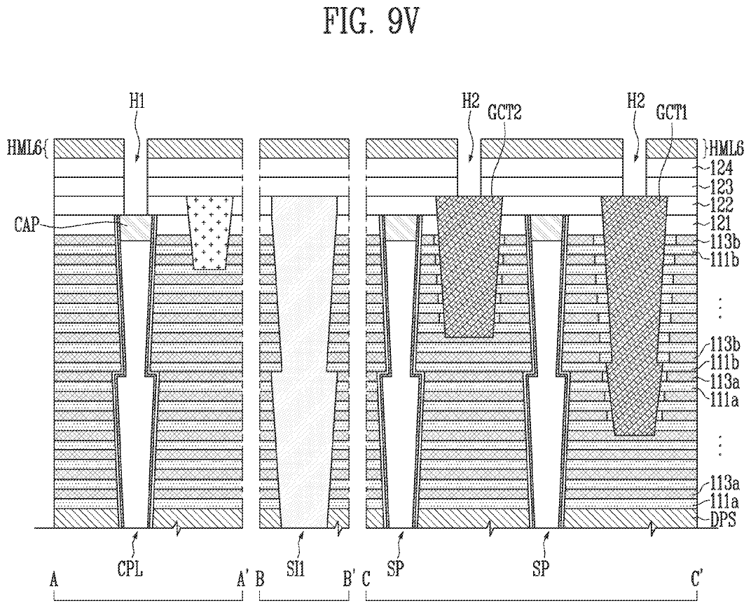

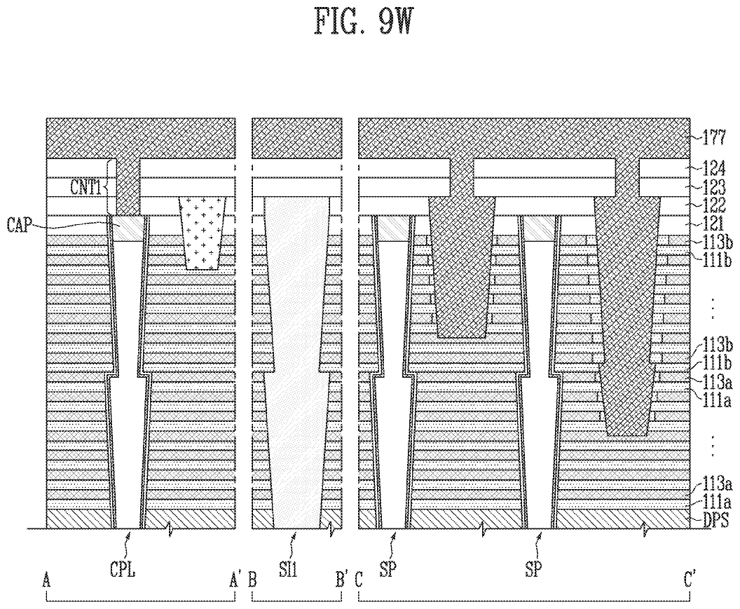

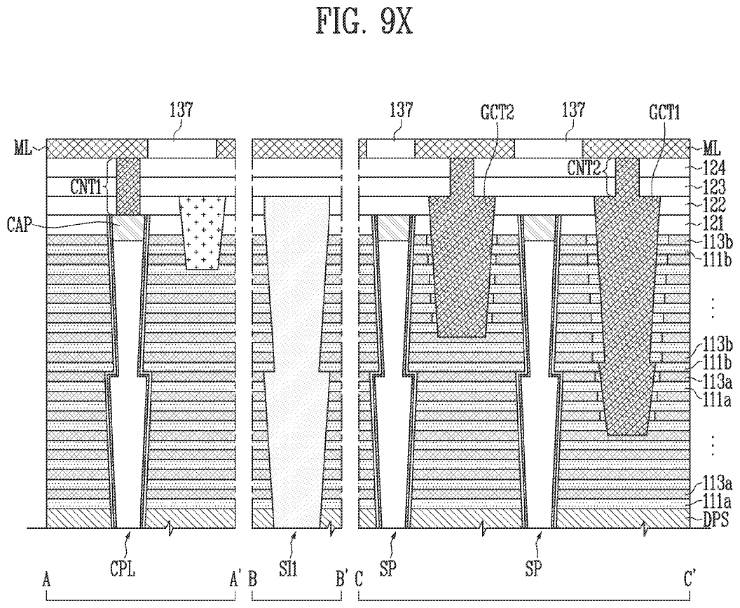

FIGS. 9A to 9X are sectional views illustrating a method of manufacturing a semiconductor memory device in accordance with an embodiment of the present disclosure. Specifically, FIGS. 9A to 9X illustrate a method of manufacturing the semiconductor memory device shown in FIGS. 4 and 5.

Referring to FIG. 9A, a plurality of first interlayer insulating layers 111a and a plurality of first sacrificial layers 115a may be alternately stacked on a lower structure (e.g., DPS). The lower structure may be various. In an embodiment, the lower structure may include the second structure ST2 and the doped semiconductor structure DPS, which are shown in FIG. 7A. In another embodiment, the lower structure may include the second structure ST2 shown in FIG. 7B and a preliminary source stack structure on the second structure ST2. The preliminary source stack structure may include the first semiconductor layer L1 and the third semiconductor layer L3, which are shown in FIG. 7B, and a sacrificial source layer (not shown) therebetween. The sacrificial source layer may be replaced with the second semiconductor layer L2 shown in FIG. 7B in a subsequent process. In still another embodiment, the lower structure may include a sacrificial substrate. The sacrificial substrate may be replaced with the doped semiconductor structure DPS as shown in FIG. 7C in a subsequent process, or a portion of the sacrificial substrate may remain as the semiconductor layer 100 as shown in FIG. 7D.

The first interlayer insulating layers 111a and the first sacrificial layers 115a may include materials having different etch selectivities with respect to an etchant used in a subsequent wet etching process. The first sacrificial layer 115a may be made of a material which may be rapidly removed through the wet etching process, as compared with the first interlayer insulating layer 111a. In an embodiment, the first interlayer insulating layer 111a may be formed of a silicon oxide, and the first sacrificial layer 115a may be formed of a silicon nitride layer.

The plurality of first interlayer insulating layers 111a and the plurality of first sacrificial layers 115a may be penetrated by a plurality of holes 1PH, 1SIH, and 1GH2 of a first group. The plurality of holes 1PH, 1SIH, and 1GH2 of the first group may include a lower plug hole 1PH for the cell plug CPL shown in FIGS. 4 and 5, a plurality of lower slit holes 1SIH for the slit SI1 shown in FIGS. 4 and 5, and a plurality of lower support holes 1GH2 for the plurality of dummy cell plugs DCPL, the plurality of main support structures SP_M1, SP_M2, and SP_M3, and the plurality of support structures SP, which are shown in FIGS. 4 and 5. In the following drawings, a process of forming the plurality of second support holes GH2 and the plurality of support structures SP therein, which are shown in FIGS. 4 and 5, is representatively illustrated. A process of forming a dummy hole form the dummy cell plug DCPL shown in FIGS. 4 and 5 and a process of forming a plurality of third support holes GH3 for the first support hole CH1 shown in FIGS. 4 and 5 and the plurality of main support structures SP_M1, SP_M2, and SP_M3 shown in FIGS. 4 and 5 are overlap with a process of forming the plurality of lower ad upper support holes for a plurality of second support holes, which will be described below, and therefore, their descriptions will be omitted.

Each of the plurality of holes 1PH, 1SIH, and 1GH2 of the first group may be filled with a first gap fill layer GL1 and a first capping layer CL1. The first gap fill layer GL1 and the first capping layer CL1 may be formed of a material having an etch selectivity with respect to the plurality of first interlayer insulating layers 111a and the plurality of first sacrificial layers 115a. In an embodiment, the first gap fill layer GL1 may include carbon. The first capping layer CL1 may be disposed on the first gap fill layer GL1. The first capping layer CL1 may include a material capable of detecting a signal for checking alignment between a plurality of holes of a second group and the plurality of holes 1PH, 1SIH, and 1GH2 of the first group. In an embodiment, the first capping layer CL1 may include a titanium nitride layer and tungsten.

Referring to FIG. 9B, a plurality of lower contact holes 1HD2 may be formed inside a first stack structure of the plurality of first interlayer insulating layers 111a and the plurality of first sacrificial layers 115a, which are alternately stacked. In an embodiment, a process of forming the plurality of lower contact holes 1HD2 may include a process of forming a buffer layer on the first stack structure, a process of forming a plurality of openings in the buffer layer, and a process of forming the plurality of lower contact holes 1HD2 having different depths by etching at least one of the plurality of first interlayer insulating layers 111a and the plurality of first sacrificial layers 115a thought the plurality of openings. The plurality of lower contact holes 1HD2 may expose the plurality of first interlayer insulating layers 111a. In the following drawings, one lower contact hole 1HD2 is representatively illustrated.

After the lower contact hole 1HD2 is formed, the lower contact hole 1HD2 may be filled with a preliminary gap fill layer GL12 and a preliminary capping layer CL12. The preliminary gap fill layer GL12 may be formed of the same material as the first gap fill layer GL1. The preliminary capping layer CL12 may be formed of a material having an etch selectivity with respect to a plurality of second interlayer insulating layers 111b and a plurality of second sacrificial layers 115b, which are formed in a subsequent process. In an embodiment, the preliminary capping layer CL12 may include poly-silicon. The preliminary capping layer CL12 may be planarized through a planarization process, and a portion of the buffer layer may remain to constitute a lowermost second interlayer insulating layer among the plurality of second interlayer insulating layers 111b.

Subsequently, the plurality of second sacrificial layers 115b and the other second interlayer insulating layers among the plurality of second interlayer insulating layers 111b may be alternately stacked on the remaining buffer layer. In an embodiment, the second interlayer insulating layer 111b may be formed of the same material as the first interlayer insulating layer 111a, and the second sacrificial layer 115b may be formed of the same material as the first sacrificial layer 115a. An insulating layer 121 may be formed on a second stack structure of the plurality of second interlayer insulating layers 111b and the plurality of second sacrificial layers 115b, which are alternately stacked.

Subsequently, a plurality of holes 2PH, 2SIH, and 2GH2 of a second group may be formed, which penetrate the second stack structure of the plurality of second interlayer insulating layers 111b and the plurality of second sacrificial layers 115b, which are alternately stacked, and the insulating layer 121. The plurality of holes 2PH, 2SIH, and 2GH2 of the second group may include an upper plug hole 2PH connected to the lower plug hole 1PH, a plurality of upper slit holes 2SIH connected to the plurality of lower slit holes 1SIH, and a plurality of upper support holes 2GH2 connected to the plurality of lower support holes 1GH2.

Each of the plurality of holes 2PH, 2SIH, and 2GH2 of the second group may be filled with a second gap fill layer GL2 and a second capping layer CL2. The second gap fill layer GL2 and the second capping layer CL2 may be formed of a material having an etch selectivity with respect to the plurality of second interlayer insulating layers 111b and the plurality of second sacrificial layers 115b. In an embodiment, the second gap fill layer GL2 may include carbon, and the second capping layer CL2 may include poly-silicon. The second capping layer CL2 may be disposed on the second gap fill layer GL2.

Referring to FIG. 9C, a mask layer HML1 may be formed on the top of the insulating layer 121. The first capping layer CL1 and the first gap fill layer GL1 in each of the lower plug hole 1PH and the plurality of lower support holes 1GH2, which are shown in FIG. 9B, and the second capping layer CL2 and the second gap fill layer GL2 in each of the upper plug hole 2PH and the plurality of upper support holes 2GH2, which are shown in FIG. 9B, may be removed through openings locally formed in the mask layer HML1. Accordingly, the lower plug hole 1PH and the upper plug hole 2PH, which are shown in FIG. 9B, may be connected to each other to be opened, thereby defining a plug hole PH, and the plurality of upper support holes 2GH2 shown in FIG. 9B may be individually connected to the plurality of lower support holes 1GH2 shown in FIG. 9B to be opened, thereby defining a plurality of second support holes GH2.

Processes performed in the dummy hole for the dummy cell plug DCPL shown in FIG. 4, processes performed in the first support hole GH1 shown in FIG. 4, and processes performed in the plurality of second support holes GH3 shown in FIG. 4 overlap with processes performed in the plurality of second support holes GH2 which will be described below, and therefore, their descriptions will be omitted.

Referring to FIG. 9D, a memory layer 135, a channel layer 133, and a core insulating layer 131 may be formed in each of the plug hole PH and a plurality of second support holes GH2. The memory layer 135 may include a blocking insulating layer, a data storage layer, and a tunnel insulating layer. In an embodiment, the data storage layer may include a silicon nitride layer capable of trapping charges. In another embodiment, the data storage layer may include a phase change material layer, a ferroelectric layer, an insulating layer including a conductive nano dot, and the like. The channel layer 133 may include silicon (Si), germanium (Ge) or any mixture thereof.

After the core insulating layer 131 is formed, a portion of the core insulating layer 131 may be etched such that an upper end of each of the plug hole PH and the plurality of second support holes GH2 is opened. After that, a semiconductor layer 171 may be formed such that the upper end of plug hole PH and the plurality of second support holes GH2, which are opened, is filled therewith.

Referring to FIG. 9E, the semiconductor layer 171 shown in FIG. 9D may be planarized, and the mask layer HML1 shown in FIG. 9D may be removed. The semiconductor layer 171 which remains may form a capping pattern CAP. At least one of an n-type impurity and a p-type impurity may be doped into the capping pattern CAP.

The memory layer 135, the channel layer 133, the core insulating layer 131, and the capping layer CAP in the plug hole PH may constitute a cell plug CPL. The memory layer 135, the channel layer 133, the core insulating layer 131, and the capping layer CAP in each of the plurality of second support holes GH2 may constitute a support structure SP.

Referring to FIGS. 9A to 9E, it can be seen that the support structure SP of the semiconductor memory device in accordance with the embodiment of the present disclosure may be manufactured through the substantially same process as the cell plug CPL. Thus, in an embodiment, it is unnecessary to add a separate process for forming the support structure SP, and accordingly, manufacturing cost of the semiconductor memory device may be reduced.

Referring to FIG. 9F, an insulating layer 122 may be formed on the insulating layer 121. In addition, a mask layer HML3 may be formed on the insulating layer 122.

Referring to FIG. 9G, a plurality of upper contact holes 2HD2 may be formed in the second stack structure of the plurality of second interlayer insulating layers 111b and the plurality of second sacrificial layers 115b through openings formed in the mask layer HML3. In an embodiment, a process of forming the plurality of upper contact holes 2HD2 may include a process of etching the insulating layers 121 and 122 through the openings formed in the mask layer HML3 and a process of forming the plurality of upper contact holes 2HD2 having different depths by etching at least one of the plurality of second interlayer insulating layers 111b and the plurality of second sacrificial layers 115b through the openings formed in the mask layer HML3. In an embodiment, the plurality of upper contact holes 2HD2 may be sequentially formed in a depth order. While the plurality of upper contact holes 2HD2 are formed, the preliminary capping layer CL12 may be used as an etch stop layer. The plurality of upper contact holes 2HD2 may expose the plurality of second interlayer insulating layers 111b and the preliminary capping layer CL12. In the following drawings, one upper contact hole exposing the preliminary capping layer CL12 among the plurality of upper contact holes 2HD2 and one upper contact hole exposing one layer among the plurality of second interlayer insulating layers 111b are representatively illustrated.

Referring to FIG. 9H, the preliminary capping layer CL12 and the preliminary gap fill layer GL12, which are shown in FIG. 9G, may be removed through the opening of the mask layer HML3. Accordingly, the lower contact hole 1HD2 shown in FIG. 9G may be opened, and at least one of the plurality of first sacrificial layers 115a may be exposed through the lower contact hole 1HD2.

Subsequently, side portions of the plurality of first sacrificial layers 115a and the plurality of second sacrificial layers 115b, which are exposed through the upper contact holes 2HD2 and the lower contact hole 1HD2, which are shown in FIG. 9G, may be etched. After that, an insulating layer may be formed such that regions in which the side portions of the plurality of first sacrificial layers 115a and the plurality of second sacrificial layers 115b are etched are filled therewith. The insulating layer may include an oxide layer. Subsequently, the insulating layer may be etched to remain as contact insulating patterns 143 in the regions in which the side portions of the plurality of first sacrificial layers 115a and the plurality of second sacrificial layers 115b are etched. A second interlayer insulating layer 111b constituting bottoms of some of the upper contact holes 2HD2 shown in FIG. 9G may be etched, and a first interlayer insulating layer 111a constituting a bottom of the lower contact hole 1HD2 may be etched. Accordingly, a plurality of contact holes having sidewalls surrounded by the contact insulating patterns 143 may be defined. The plurality of contact holes may include the first contact hole HD1 and the plurality of second contact holes HD2, which are shown in FIG. 4. The plurality of second contact holes HD2 may include a second contact hole of a first type, which exposes each of the plurality of first sacrificial layers 115a and a second contact hole of a second type, which exposed each of the plurality of second sacrificial layers 115b. Another of the plurality of second sacrificial layers 115b may be exposed by a first contact hole (HD1 shown in FIG. 4). In the following drawings, one second contact hole HD2 of the first type and one second contact hole HD2 of the second type are representatively illustrated.

The contact insulating pattern 143 may surround a side of each of the second contact holes HD2. The contact insulating pattern 143 may be interposed between two interlayer insulating layers adjacent to each other in a length direction.

Referring to FIG. 9I, a third gap fill layer GL3 and a third capping layer CL3 may be formed in each of the second contact holes HD2. The third gap fill layer GL3 and the third capping layer CL3 may be formed of a material having an etch selectivity with respect to the plurality of first interlayer insulating layers 111a, the plurality of first sacrificial layers 115a, the plurality of second interlayer insulating layers 111b, and the plurality of second sacrificial layers 115b. In an embodiment, the third gap fill layer GL3 may include carbon, and the third capping layer CL3 may include poly-silicon. The third capping layer CL3 may be disposed on the third gap fill layer GL3.

Referring to FIG. 9J, a mask layer HML4 may be formed on the insulating layer 122 such that the third capping layer CL3 is covered thereby. The insulating layer 122 may be etched through an opening of the mask layer HML4, and the first gap fill layer GL1, the first capping layer CL1, the second gap fill layer GL2, and the second capping layer CL2, which are shown in FIG. 9I, may be removed. Accordingly, the plurality of upper slit holes 2SIH may be individually connected to the plurality of lower slit holes 1SIH shown in FIG. 9I to be opened, thereby defining a plurality of slit holes SIH. The plurality of slit holes SIH may be arranged in a line as shown in FIG. 4. Subsequently, the plurality of first interlayer insulating layers 111a, the plurality of first sacrificial layers 115a, the plurality of second interlayer insulating layers 111b, and the plurality of second sacrificial layers 115b at the periphery of the plurality of slit holes SIH may be etched such that the plurality of slit holes SIH are connected to each other. Through such an etching process, the plurality of slit holes SIH arranged in a line, which are shown in FIG. 4, may be extended to be connected to each other, so that a slit SI1 having a line shape is formed.

Referring to FIG. 9K, the first and second sacrificial layers 115a and 115b shown in FIG. 9J may be selectively removed through the slit SI1, using a wet etching technique. When the first and second sacrificial layers 115a and 115b are formed of a silicon nitride layer, a phosphoric acid solution may be used as an etchant for selectively removing the first and second sacrificial layers 115a and 115b. As the first and second sacrificial layers 115a and 115b are removed, recesses may be formed between the first and second sacrificial layers 115a and 115b. Spaces between the first and second sacrificial layers 115a and 115b may be supported by the plurality of support structures SP, and the dummy cell plug DCPL and the plurality of main support structures SP_M1, SP_M2, and SP_M3, which are shown in FIG. 4.

After that, the recesses may be filled with first and second conductive layers 113a and 113b. The first and second conductive layers 113a and 113b may include at least one of a metal layer, a metal silicide layer, a metal nitride layer, and a doped silicon layer. In an embodiment, the first and second conductive layers 113a and 113b may include a low-resistance metal such as tungsten to achieve low resistance wiring. However, the metal is not limited thereto, and may include, for example, molybdenum.

Referring to FIG. 9L, the slit SI1 may be filled with an insulating material SLR.

Referring to FIG. 9M, a portion of the insulating material SLR shown in FIG. 9L may be removed such that the insulating material SLR remains as a vertical structure 141 in the slit SI1. In addition, the mask layer HML4 shown in FIG. 9L may be removed such that the third capping layer CL3 is exposed.

Referring to FIG. 9N, a mask layer HML5 for forming the drain select isolation structure DSI shown in FIGS. 4 and 5 may be formed.

Referring to FIG. 9O, a recess RE penetrating at least an uppermost second conductive layer among the second conductive layers 113a may be formed through an opening of the mask layer HML5.

Referring to FIG. 9P, the mask layer HML5 shown in FIG. 9O may be removed. Subsequently, an insulating layer 173 may be applied such that the recess RE shown in FIG. 9O is filled therewith.

Referring to FIG. 9Q, a portion of the insulating layer 173 shown in FIG. 9P on the insulating layer 122 may be removed such that the insulating layer 173 remains as a drain select isolation structure DSI inside the recess RE shown in FIG. 9O. The third capping layer CL3 may be exposed.

Referring to FIG. 9R, the third capping layer CL3 and the third gap fill layer GL3, which are shown in FIG. 9Q, may be removed. Accordingly, the inside of each of the plurality of second contact holes HD2 may be exposed. In the same manner, the inside of each of the plurality of first contact holes HD1 shown in FIG. 4 may be exposed. The first and second conductive layers 113a and 113b may be exposed through bottoms of the plurality of second contact holes HD2 and the plurality of first contact holes HD1 shown in FIG. 4. The contact insulating pattern 143 may block the first and second conductive layers 113a and 113b from being exposed by sidewalls of the plurality of second contact holes HD2 and the plurality of first contact holes HD1 shown in FIG. 4.

Referring to FIG. 9S, a conductive layer 175 may be formed on the insulating layer 122 such that the second contact holes HD2 are filled therewith.

Referring to FIG. 9T, as the conductive layer 175 on the insulating layer 122 shown in FIG. 9S is removed, the conductive layer shown in FIG. 9S may be isolated into a plurality of conductive gate contacts GCT1 and GCT2.

Referring to FIG. 9U, insulating layers 123 and 124 may be additionally formed on the insulating layer 122, and a mask layer HML6 for a bit line contact CNT1 and a connection contact CNT2 may be formed on the insulating layer 124.

Referring to FIG. 9V, a first hole H1 and a plurality of second holes H2, which penetrate the insulating layers 122, 123, and 124, may be formed through openings of the mask layer HML6. The first hole H1 may open the cell plug CPL and the capping pattern CAP, and the plurality of second holes H2 may open the plurality of conductive gate contacts GCT1 and GCT2.

Referring to FIG. 9W, a conductive layer 177 may be formed on the top of the mask layer HML6 such that the first hole H1 and the plurality of second holes H2 are filled therewith.

Referring to FIG. 9X, as the conductive layer 177 on the insulating layer 124 shown in FIG. 9V is removed, the conductive layer 177 shown in FIG. 9V may be isolated into a first contact CNT1 and a plurality of second contacts CNT2.

Subsequently, an insulating structure 137 and conductive lines ML inside the insulating structure 137 may be formed on the top of the insulating layer 124.

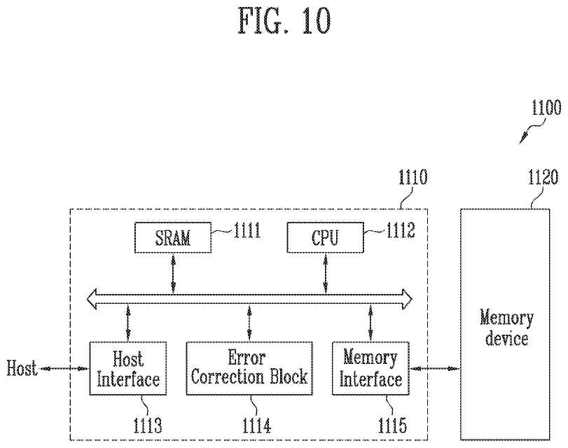

FIG. 10 is a block diagram illustrating a configuration of a memory system in accordance with an embodiment of the present disclosure.

Referring to FIG. 10, the memory system 1100 includes a memory device 1120 and a memory controller 1110.

The memory device 1120 may be a multi-chip package configured with a plurality of flash memory chips. The memory device 1120 may include a cell plug, a plurality of conductive gate contacts connected to a plurality of conductive layers of a stack structure, and a plurality of support structures. The plurality of support structures may be disposed in substantially a circle to be spaced apart from a center of each of the conductive gate contacts at the same distance. Also, the plurality of support structures may be provided using a process of forming the cell plug.

The memory controller 1110 may be configured to control the memory device 1120. The memory controller 1110 may include Static

Random Access Memory (SRAM) 1111, a Central Processing Unit (CPU) 1112, a host interface 1113, an error correction block 1114, and a memory interface 1115. The SRAM 1111 is used as operation memory of the CPU 1112, the CPU 1112 performs various control operations for data exchange of the memory controller 1110, and the host interface 1113 includes a data exchange protocol for a host connected with the memory system 1100. The error correction block 1114 detects errors included in a data read from the memory device 1120, and corrects the detected errors. The memory interface 1115 interfaces with the memory device 1120. The memory controller 1110 may further include Read Only Memory (ROM) for storing code data for interfacing with the host, and the like.

The above-described memory system 1100 may be a memory card or a Solid State Disk (SSD), in which the memory device 1120 is combined with the controller 1110. For example, when the memory system 1100 is an SSD, the memory controller 1100 may communicate with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, Parallel-ATA (PATA) protocol, Small Computer System Interface (SCSI) protocol, Enhanced Small Disk Interface (ESDI) protocol, and Integrated Drive Electronics (IDE) protocol.

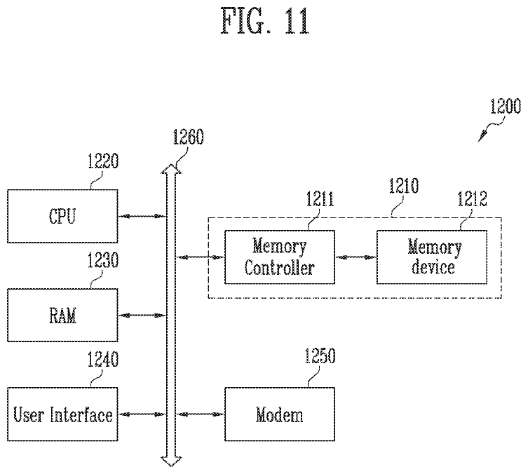

FIG. 11 is a block diagram illustrating a configuration of a computing system in accordance with an embodiment of the present disclosure.

Referring to FIG. 11, a computing system 1200 may include a CPU 1220, random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, mobile DRAM, and the like may be further included.

The memory system 1210 may include a memory device 1212 and a memory controller 1211.

The memory device 1212 may have the same configuration as the memory device 1120 described above with reference to FIG. 10.

According to an embodiment of the present disclosure, a phenomenon in which a stack structure is bent may be reduced and prevented by support structures disposed around a conductive gate contact. In addition, in an embodiment, the support structures may be formed using a process of forming a cell plug, and thus the number of additional processes for forming the support structures may be minimized.

What is claimed is:

1. A semiconductor memory device comprising:
a stack structure including a cell array region and a contact region extending in a first direction from the cell array region;
a cell plug penetrating the cell array region of the stack structure;
a conductive gate contact penetrating the contact region of the stack structure; and
a plurality of first support structures bordering a perimeter of the conductive gate contact and disposed to be spaced apart from the center of the conductive gate contact at a first distance.

2. The semiconductor memory device of claim 1, the plurality of first support structures are disposed in substantially a circle to be spaced apart from the center of the conductive gate contact at the first distance.

3. The semiconductor memory device of claim 1,
wherein the stack structure includes a source select line, a plurality of word lines, and a drain select line, which are stacked to be spaced apart from each other in a length direction of the cell plug, and
wherein the conductive gate contact is in contact with one of the source select line, the plurality of word lines, and the drain select line.

4. The semiconductor memory device of claim 1,
wherein each of the cell plug and the plurality of first support structures includes:
a channel layer; and
a memory layer between the channel layer and the stack structure.

5. The semiconductor memory device of claim 1,
wherein at least one of the plurality of first support structures is formed of an insulating material filling a support hole penetrating the stack structure.

6. The semiconductor memory device of claim 1, further comprising a plurality of second support structures bordering a perimeter of the conductive gate contact and disposed to be spaced apart from the center of the conductive gate contact at a second distance greater than the first distance.

7. The semiconductor memory device of claim 6, the plurality of second support structures are disposed in substantially a circle to be spaced part from the center of the conductive gate contact at the second distance.

8. The semiconductor memory device of claim 6, wherein a number of the second support structures is greater than or equal to a number of the first support structures.

9. The semiconductor memory device of claim 1, further comprising a plurality of main support structures penetrating the contact region of the stack structure.

10. The semiconductor memory device of claim 9,
wherein the plurality of main support structures are arranged in a zigzag form.

11. The semiconductor memory device of claim 9, wherein the plurality of main support structures includes:
n first main support structures constituting a first column, the n first main support structures being arranged in a line in the first direction;
(n−1) second main support structures constituting a second column adjacent to the first column in a second direction intersecting the first direction, the (n−1) second main support structures being arranged in a line in the first direction; and
a plurality of third main support structures adjacent to the plurality of first support structures,
wherein a separation distance between a first support structure and a third main support structure, which are adjacent to each other, among the plurality of first support structures and the plurality of third main support structures is different from a separation distance between the n first main support structures or a separation distance between the (n−1) second main support structures, and
wherein n is a natural number equal to or greater than 2.

12. The semiconductor memory device of claim 1,
wherein the stack structure includes a plurality of interlayer insulating layers and a plurality of conductive layers, which are alternately stacked in a length direction of the cell plug.

13. A method of manufacturing a semiconductor memory device, the method comprising:
forming a stack structure by alternately stacking a plurality of interlayer insulating layers and a plurality of sacrificial layers;
forming a first hole and a plurality of second holes to penetrate the stack structure;
forming a memory layer and a channel layer in each of the first hole and the plurality of second holes; and
forming a third hole in the stack structure, the third hole having a bottom exposing one sacrificial layer among the plurality of sacrificial layers,
wherein the plurality of second holes are disposed in substantially a circle to be spaced apart from the center of the third hole at a first distance.

14. The method of claim 13,
wherein the memory layer and the channel layer constitute a cell plug inside the first hole, and
wherein the memory layer and the channel layer constitute a plurality of support structures inside the plurality of second holes.

15. The method of claim 14, further comprising forming a plurality of main support structures penetrating the stack structure,
wherein the stack structure includes a cell array region and a contact region extending from the cell array region,
wherein the cell plug is formed in the cell array region of the stack structure,
wherein the plurality of support structures and the third hole are formed in the contact region of the stack structure, and
wherein the contact region includes a first region occupied by the plurality of support structures and the third hole and a second region in which the plurality of main support structures are formed.

16. The method of claim 15,
wherein the forming of the plurality of main support structures includes:
forming a plurality of fourth holes, using the forming of the first hole and the plurality of second holes; and
forming the plurality of main support structures in the plurality of fourth holes, using the forming of the memory layer and the channel layer of each of the cell plug and the plurality of support structures.

17. The method of claim 13, further comprising:
etching side portions of the plurality of sacrificial layers, the side portions exposed through the third hole;
forming a contact insulating pattern in each of regions where the side portions of the plurality of sacrificial layers are etched, the contact insulating pattern surrounding a sidewall of the third hole;
forming a gap fill layer in the third hole;
replacing the plurality of sacrificial layers with a plurality of conductive layers;
exposing one conductive layer among the plurality of conductive layers through the bottom of the third hole by removing the gap fill layer; and
forming a conductive gate contact connected to the exposed conductive layer, the conductive gate contact filling the third hole.

18. The method of claim 13, further comprising forming a plurality of fourth holes disposed in a circle to be spaced apart from the center of the third hole at a second distance greater than the first distance.

19. A method of manufacturing a semiconductor memory device, the method comprising:
alternately stacking a plurality of interlayer insulating layers and a plurality of sacrificial layers;
forming a contact hole penetrating at least one of the plurality of interlayer insulating layers and the plurality of sacrificial layers;
forming a gap fill layer in the contact hole;
forming a cell plug, a plurality of main support structures, and a plurality of support structures, which penetrate the plurality of interlayer insulating layers and the plurality of sacrificial layers;
replacing the plurality of sacrificial layers with a plurality of conductive layers;
removing the gap fill layer such that one conductive layer among the plurality of conductive layers is exposed through a bottom of the contact hole; and
forming a conductive gate contact in a region in which the gap fill layer is removed,
wherein the plurality of support structures are arranged in substantially a circle around the contact hole.

20. The method of claim 19,
wherein the plurality of support structures are arranged in substantially a circle to be spaced apart from a center of the contact hole at a first distance.

21. The method of claim 19,
wherein the plurality of support structures include:
a plurality of first support structures arranged in substantially a circle to be spaced apart from the center of the contact hole at a first distance; and
a plurality of second support structures arranged in substantially a circle to be spaced apart from the center of the contact hole at a second distance greater than the first distance.

22. The method of claim 19,
wherein the plurality of main support structures may be respectively disposed on a first column and a second column, which are alternately arranged between the plurality of support structures and the cell plug,
wherein n first main support structures among the plurality of main support structures are arranged on the first column,
wherein (n−1) second main support structures among the plurality of main support structures are arranged on the second column, and
wherein n is a natural number equal to or greater than 2.
